(19) United States
(12) Patent Application Publication
(10) Pub. No.: US 2026/0123188 A1
(43) Pub. Date: Apr. 30, 2026

(54) DISPLAY DEVICE AND ELECTRONIC DEVICE INCLUDING THE SAME

(71) Applicant: Samsung Display Co., LTD., Yongin-si (KR)

(72) Inventors: JIYUN PARK, Yongin-si (KR); SUK HOON KANG, Yongin-si (KR); SUJI PARK, Yongin-si (KR); MINSEOK LEE, Yongin-si (KR); HO LIM, Yongin-si (KR); SUK-KUNG CHEI, Yongin-si (KR)

(21) Appl. No.: 19/343,324

(22) Filed: Sep. 29, 2025

(30) Foreign Application Priority Data
Oct. 28, 2024 (KR) 10-2024-0148683

(51) Int. Cl. H10K 59/122; H10K 59/38

(52) U.S. Cl. CPC H10K 59/122; H10K 59/38

(57) ABSTRACT

A display device includes a light emitting element, which outputs a source light, and an optical structure layer disposed on the light emitting element, and which converts the source light into a light of a different wavelength. The optical structure layer includes a light control layer disposed on the light emitting element, and including a first bank, in which a first bank opening is defined, and a first light control pattern disposed in the first bank opening, a second bank disposed on the light control layer, and in which a second bank opening overlapping the first bank opening in a plan view is defined, a color filter layer disposed on the second bank, and an adhesion layer disposed between the second bank and the color filter layer.

This application claims priority to Korean Patent Application No. 10-2024-0148683, filed on Oct. 28, 2024, and all the benefits accruing therefrom under 35 U.S.C. § 119, the content of which in its entirety is herein incorporated by reference.

### BACKGROUND

Embodiments of the present disclosure described herein relate to a display device and an electronic device including the same.

A display panel includes a transmissive display panel that selectively transmits a source light generated from a light source, and a light emitting display panel that generates a source light from the display panel itself. The display panel device may include different types of light control patterns depending on pixels to generate an image. The light control pattern may transmit a partial wavelength range of the source light or may convert a color of the source light. Some light control patterns may change the characteristics of the light without changing the color of the source light.

### SUMMARY

Embodiments of the present disclosure provide a display device with an improved optical efficiency.

Embodiments of the present disclosure provide an electronic device including a display device with an improved optical efficiency.

According to an embodiment, a display device includes a light emitting element, which outputs a source light, and an optical structure layer disposed on the light emitting element, and which converts the source light into a light of a different wavelength. The optical structure layer includes a light control layer disposed on the light emitting element, and including a first bank, in which a first bank opening is defined, and a first light control pattern disposed in the first bank opening, a second bank disposed on the light control layer, and in which a second bank opening overlapping the first bank opening in a plan view is defined, a color filter layer disposed on the second bank, and an adhesion layer disposed between the second bank and the color filter layer.

The second bank may include an organic material or an inorganic material.

An air layer may be disposed in the second bank opening.

A thickness of the second bank may be 3 micrometers (μm) to 5μm μm.

In a plan view, an opening overlapping the second bank opening may be defined in the adhesion layer.

An air layer may be disposed in the opening.

A thickness of the adhesion layer may be 3μm to 5μm.

The adhesion layer may include a photocurable resin or a thermophotovoltaic resin.

The adhesion layer may include acrylate or epoxide.

A curing temperature of the adhesion layer may be 80 degrees Celsius (° C.) to 100 degrees Celsius.

A transition temperature of the adhesion layer may be 50 degrees Celsius to 80 degrees Celsius.

The first bank opening may be provided in plurality, and the first light control pattern, a second light control pattern, and a third light control pattern may be disposed in the plurality of first bank openings, respectively.

The second bank opening may be provided in plurality, and in the plan view, the plurality of second bank openings may overlap the first bank openings, respectively.

An air layer may be disposed in the plurality of second bank openings.

A plurality of openings overlapping the plurality of second bank openings may be defined in the adhesion layer, and an air layer may be disposed in the openings.

According to an embodiment, an electronic device includes a camera module, a display device, which displays an image corresponding to a captured image acquired through the camera module, and a case accommodating the display device and the camera module. The display device includes a light emitting element, which outputs a source light, and an optical structure layer disposed on the light emitting element, and which converts the source light into a light of a different wavelength, and the optical structure layer includes a light control layer disposed on the light emitting element, and including a first bank, in which a first bank opening is defined, and a first light control pattern disposed in the first bank opening, a second bank disposed on the light control layer, and in which a second bank opening overlapping the first bank opening in a plan view is defined, a color filter layer disposed on the second bank, and an adhesion layer disposed between the second bank and the color filter layer.

An air layer may be disposed in the second bank opening.

In a plan view, an opening overlapping the second bank opening may be defined in the adhesion layer, and an air layer may be defined in the opening.

The first bank opening may be provided in plurality, and the first light control pattern, a second light control pattern, and a third light control pattern may be disposed in the plurality of first bank openings, respectively. The second bank opening may be provided in plurality, and in the plan view, the plurality of second bank openings overlap the first bank openings, respectively, and an air layer may be disposed in the plurality of second bank openings.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment.

FIG. 2 is an exploded perspective view of an electronic device according to an embodiment.

FIG. 3 is a block diagram of the electronic device illustrated in FIG. 2.

FIG. 4 is a cross-sectional view of a display panel according to an embodiment of the present disclosure.

FIG. 5 is a plan view of a display panel according to an embodiment of the present disclosure.

FIG. 6 is an enlarged plan view of a portion of a display panel according to an embodiment.

FIG. 7 is a cross-sectional view of a portion of a display panel, taken along line I-I′ of FIG. 6 according to an embodiment of the present disclosure.

FIG. 8 is a cross-sectional view illustrating a portion of a display panel, taken along line II-II′ of FIG. 6 according to an embodiment of the present disclosure.

FIG. 9 is a cross-sectional view illustrating a portion of a display panel, taken along line II-II′ of FIG. 6 according to another embodiment of the present disclosure.

FIG. 10 is a cross-sectional view of a light emitting element according to an embodiment of the present disclosure.

### DETAILED DESCRIPTION

In the specification, the expression that a first component (or region, layer, part, etc.) is “on”, “connected with”, or “coupled with” a second component may mean that the first component is directly on, connected with, or coupled with the second component or means that a third component is interposed therebetween.

The same reference numerals may refer to the same components. Also, in drawings, the thickness, ratio, and dimension of components are exaggerated for effectiveness of description of technical contents. The term “and/or” may include one or more combinations in each of which associated elements are defined.

Although the terms “first”, “second”, “(1-1)-th”, “(1-2)-th”, etc. may be used to describe various components, the components should not be construed as being limited by the terms. The terms are only used to distinguish one component from another component. For example, without departing from the scope and spirit of the present disclosure, a first component may be referred to as a second component, and similarly, the second component may be referred to as the first component. The terms of a singular form may include plural forms unless otherwise specified.

Also, the terms “under”, “below”, “on”, “above”, etc. are used to describe the correlation of components illustrated in drawings. The terms are relative concepts, and are described with respect to directions indicated in the drawings.

It will be understood that the terms “include”, “comprise”, “have”, etc. specify the presence of features, numbers, steps, operations, elements, or components, described in the specification, or a combination thereof, not precluding the presence or additional possibility of one or more other features, numbers, steps, operations, elements, or components or a combination thereof.

Unless otherwise defined, all terms (including technical terms and scientific terms) used in the specification have the same meaning as commonly understood by one skilled in the art to which the present disclosure belongs. Furthermore, terms such as terms defined in the dictionaries commonly used should be interpreted as having a meaning consistent with the meaning in the context of the related technology, and should not be interpreted in ideal or overly formal meanings unless explicitly defined herein.

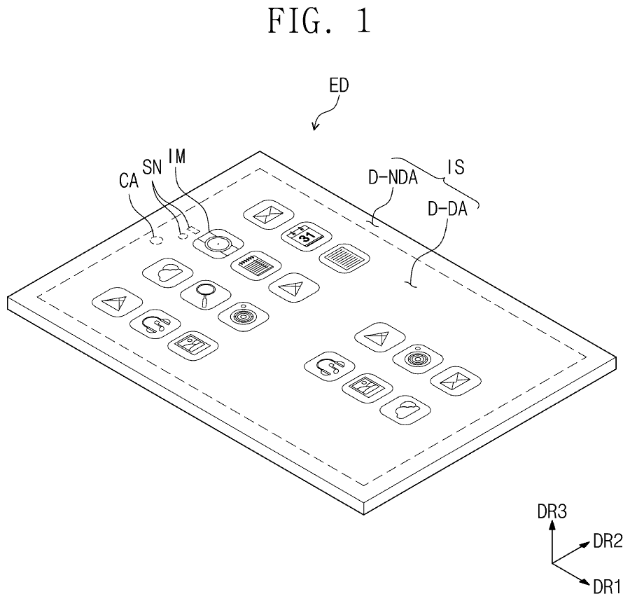

FIG. 1 is a perspective view of a display device according to an embodiment.

Referring to FIG. 1, an electronic device ED may be a device that is activated depending on an electrical signal to display an image. The electronic device ED may include various embodiments, and for example, the electronic device ED may include a small and medium-sized device, such as a monitor, a mobile phone, a tablet computer, a navigation device, and a game console, including a large device, such as a television and an external billboard. Meanwhile, the embodiments of the electronic device ED is exemplary, and is not limited to any one as long as it does not deviate from the concept of the present disclosure.

In the specification, a thickness direction of the electronic device ED may be a direction that is parallel to a third direction DR3 that is a normal direction of a plane defined by a first direction DR1 and a second direction DR2. In the specification, front surfaces (or top surfaces) and rear surfaces (or lower surfaces) of members that constitute the electronic device ED may be defined with respect to the third direction DR3.

The electronic device ED may display an image IM in the third direction DR3 through a display surface IS that is parallel to a plane defined by the first direction DR1 and the second direction DR2. The third direction DR3 may be parallel to a normal direction “N” of the display surface IS. The display surface IS, on which the image IM is displayed, may correspond to a front surface of the electronic device ED. The image IM may include a still image as well as a moving image. FIG. 1 illustrates icon images as an example of the image IM.

In the specification, “in a plan view” may be defined as a state, in which it is viewed from a thickness direction (i.e., the third direction DR3) of the display device DD. In the specification, “on a cross-section” may be defined as a state, in which it is viewed from the first direction DR1 or the second direction DR2. Meanwhile, directions that are indicated by the first to third directions DR1, DR2, and DR3 may be converted into other directions as relative concepts.

FIG. 1 illustrates an electronic device ED having a flat display surface IS by way of example. However, a shape of the display surface IS of the electronic device ED is not limited thereto, and may be a curved shape or a three-dimensional shape in another embodiment.

The electronic device ED may be flexible. The term “flexible” means a flexible characteristic, and may include those from a completely folded structure to a structure that may be bent at a level of several nanometers. For example, the flexible electronic device ED may include a curved display device or a foldable display device. However, the present disclosure is not limited thereto, and the electronic device ED may be rigid in another embodiment.

The display surface IS of the electronic device ED may include a display area D-DA and a peripheral area D-NDA. The image IM may be displayed on the display area D-DA. The user may visually recognize the image IM through the display area D-DA. In the embodiments illustrated in FIG. 1 and the like, the display area D-DA has a rectangular shape, but this is illustrated by way of example, and the display area D-DA may have various shapes.

The peripheral area D-NDA may be a non-display portion that does not display an image IM. The peripheral area D-NDA has a specific color and may correspond to a portion that shields light. The peripheral area D-NDA may be adjacent to the display area D-DA. For example, the peripheral area D-NDA may be disposed on an outskirt of at least one side of the display area D-DA, and the peripheral area D-NDA may surround the display area D-DA. However, this is illustrated by way of example, and the peripheral area D-NDA may be disposed adjacent to only one side of the display area D-DA, or may be disposed on not the front surface but a side surface of the electronic device ED, and the present disclosure is not limited thereto, and the peripheral area D-NDA may be omitted in another embodiment.

The electronic device ED may include at least one sensor SN and at least one camera CA. The sensor SN and the camera CA may be adjacent to a periphery of the electronic device ED. The sensor SN and the camera CA may be disposed in a display area D-DA that is adjacent to the peripheral area D-NDA.

Light may be transmitted through portions of the electronic device ED, at which the sensor SN and the camera CA are disposed, to be provided to the camera CA and the sensor SN. By way of example, the sensor SN may be a proximity light sensor, but the type of the sensor SN is not limited thereto. The camera CA may photograph an external image. A plurality of sensors SN and a plurality of cameras CA may be provided.

Meanwhile, the electronic device ED according to an embodiment may sense an external input that is applied from the outside. The external input may have various forms, such as a pressure, a temperature, and a light provided from the outside. The external input may include not only an input that contacts the electronic device ED (e.g., a contact by a user's hand or a pen), but also an input (e.g., hovering) that is applied close to the electronic device ED.

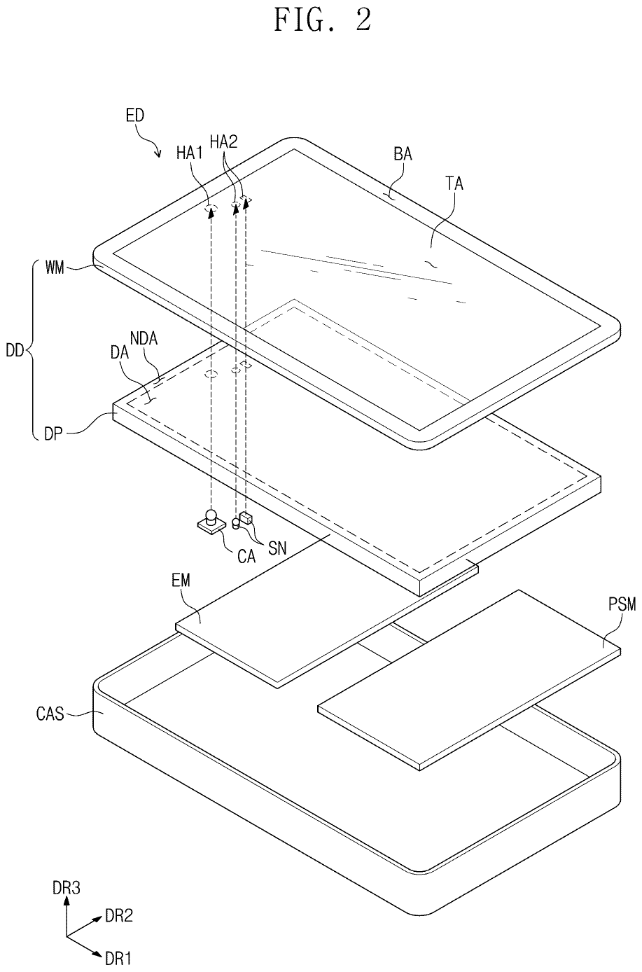

FIG. 2 is an exploded perspective view of an electronic device according to an embodiment.

Referring to FIG. 2, the electronic device ED may include a window WM, a display panel DP, and a case CAS, and a display device DD may include the window WM and the display panel DP. The window WM and the case CAS may be coupled to each other to define an exterior of the electronic device ED, and provide an internal space, in which components of the electronic device ED, such as the display panel DP, may be accommodated.

The window WM may be disposed on the display panel DP. The window WM may protect the display panel DP from an external impact. A front surface of the window WM may correspond to the display surface IS of the electronic device ED described above. The front surface of the window WM may include a transmission area TA and a bezel area BA.

The transmission area TA of the window WM may be an optically transparent area. The window WM may transmit an image provided by the display panel DP through the transmission area TA, and the user may visually recognize the image. The transmission area TA may correspond to the display area D-DA of the electronic device ED.

The window WM may include an optically transparent insulating material. For example, the window WM may include glass, sapphire, or plastic. The window WM may have a single-layered or multi-layered structure. The window WM may further include functional layers, such as an anti-fingerprint layer, a phase control layer, and a hard coating layer, which are disposed on an optically transparent substrate.

The bezel area BA of the window WM may be provided as an area, in which a material including a specific color is deposited, coated, or printed. The bezel area BA of the window WM may prevent a component of the display panel DP, which is disposed to overlap the bezel area BA, from being visually recognized outside. The bezel area BA may correspond to the peripheral area D-NDA of the electronic device ED.

At least one first hole area HA1 and a plurality of second hole areas HA2 may be defined in the window WM. The camera CA may be disposed in the first hole area HA1, and sensors SN may be disposed in the second hole areas HA2.

The display panel DP may display an image in response to an electrical signal. The display panel DP may include a display area DA and a non-display area NDA that is adjacent to the display area DA.

The display area DA may be a portion corresponding to the display area D-DA (FIG. 1) of the electronic device ED. The display area DA may be an area that is activated by an electrical signal. The display area DA may be an area that outputs an image provided from the display panel DP. The display area DA of the display panel DP may correspond to the above-described transmission area TA. Meanwhile, in this specification, “an area/portion corresponds to another area/portion” means “an area/portion overlaps another area/portion”, and is not limited to having the same area and/or the same shape. The image displayed on the display area DA may be visually recognized from the outside through the transmission area TA.

The non-display area NDA may be adjacent to the display area DA. For example, the non-display area NDA may surround the display area DA. However, the present disclosure is not limited thereto, and the non-display area NDA may be defined in various shapes. The non-display area NDA may be a portion corresponding to a peripheral area D-NDA (FIG. 1) of the electronic device ED. The non-display area NDA may be an area, in which driving circuits or driving wirings for driving the display area DA, various signal lines that provide electrical signals, and pads are disposed. The non-display area NDA of the display panel DP may correspond to the above-described bezel area BA. Components of the display panel DP disposed in the non-display area NDA may be prevented from being visually recognized by the bezel area BA.

The display panel DP according to an embodiment may be a light emitting display panel, and the present disclosure is not particularly limited thereto. For example, the display panel DP may be an organic light emitting display panel, an inorganic light emitting display panel, or a quantum dot light emitting display panel. A light emission layer of the organic light emitting display panel may include an organic light emitting material, and a light emission layer of the inorganic light emitting display panel may include an inorganic light emitting material. A light emission layer of the quantum dot light emitting display panel may include a quantum dot and a quantum rod. Hereinafter, it is described that the display panel DP is an organic light emitting display panel.

The display panel DP may include a base substrate BS, a circuit element layer DP-CL, a display element layer DP-LED, and a thin film encapsulation layer TFE. Each layer of the display panel DP will be described below in more detail.

The case CAS may be disposed under the display panel DP to accommodate the display panel DP. The case CAS may absorb an impact applied from the outside, and may protect the display panel DP by preventing foreign/moisture that penetrates into the display panel DP. The case CAS according to an embodiment may be provided in a form, in which a plurality of accommodation members are coupled to each other.

Meanwhile, the display panel DP may further include an input sensing unit. The input sensing unit may acquire coordinate information of an external input applied from the outside of the electronic device ED. For example, the input sensing unit may be disposed directly on the display panel DP through a continuous process or may be separately manufactured and attached to the display panel DP through an adhesion layer.

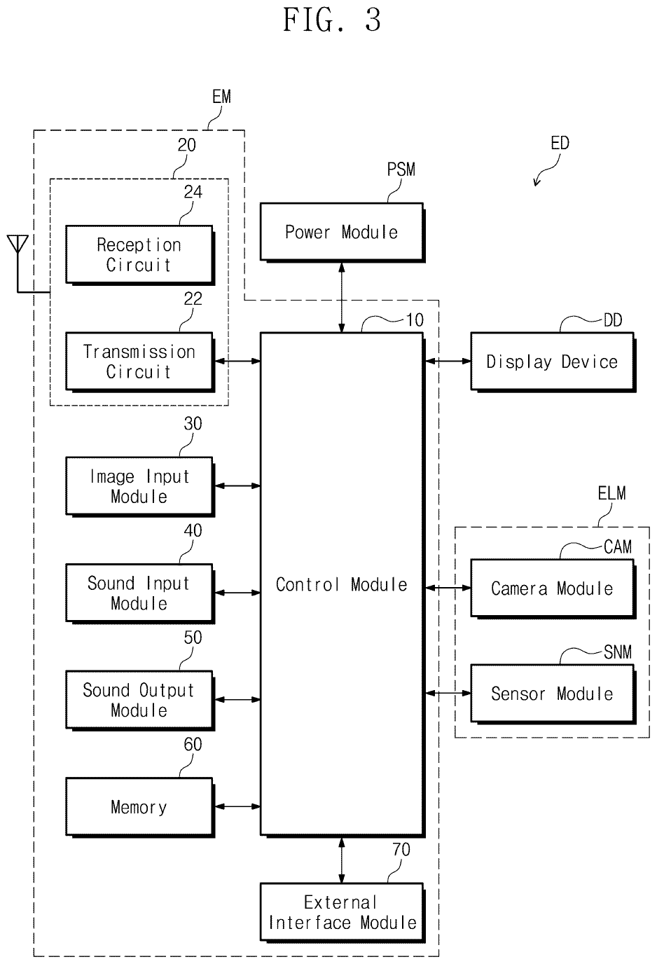

FIG. 3 is a block diagram of the electronic device illustrated in FIG. 2.

Referring to FIG. 3, the electronic device ED may include an electronic module EM, a power module PSM, a display device DD, and an electronic optical module ELM. The electronic module EM may include a control module 10, a wireless communication module 20, an image input module 30, a sound input module 40, a sound output module 50, a memory 60, and an external interface module 70. The modules may be mounted on a circuit board or may be electrically connected through a flexible circuit board. The electronic module EM may be electrically connected to the power supply module PSM.

The control module 10 may control an overall operation of the electronic device ED. For example, the control module 10 may activate or deactivate the display device DD according to a user input. The control module 10 may control the image input module 30, the sound input module 40, and the sound output module 50 according to a user input. The control module 10 may include at least one microprocessor.

The wireless communication module 20 may transmit/receive a wireless signal with another terminal by using Bluetooth or Wi-Fi. The wireless communication module 20 may transmit/receive voice signals by using general communication lines. The wireless communication module 20 may include a transmission circuit 22 that modulates and transmits a transmission signal, and a reception circuit 24 that demodulates the received signal.

The image input module 30 may convert an image signal into image data to be displayed on the display device DD by processing the image signal. The sound input module 40 may receive an external sound signal from a microphone in a recording mode and a voice recognition mode, or the like and then may convert the external sound signal into electrical voice data. The sound output module 50 may convert audio data received from the wireless communication module 20 or audio data stored in the memory 60 and then may output the converted data to the outside.

The external interface module 70 may operate as an interface that connects to an external charger, a wired/wireless data port, a card socket (e.g., a memory card, a SIM/UIM card, or the like), or the like.

The power module PSM may supply power for overall operations of the electronic device ED. The power module PSM may include a general battery device.

The electronic optical module ELM may be an electronic component that outputs or receives an optical signal. The electronic optical module ELM may transmit or receive an optical signal through a partial area of the display device DD. In an embodiment, the electronic optical module ELM may include a camera module CAM and a sensor module SNM. The camera module CAM may include the camera CA illustrated in FIG. 2. The sensor module SNM may include the sensor SN illustrated in FIG. 2.

The electronic device ED may include a camera module CAM, and may include the display device DD that displays an image corresponding to the captured image acquired through the camera module CAM.

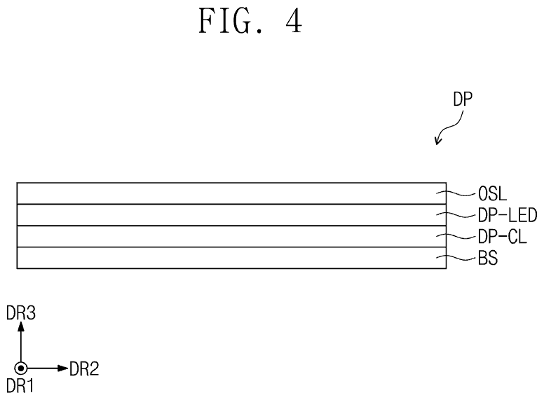

FIG. 4 is a cross-sectional view of a display panel according to an embodiment of the present disclosure.

Referring to FIG. 4, the display panel DP may include a base substrate BS, a circuit element layer DP-CL, a display element layer DP-LED, and an optical structure layer OSL. The base substrate BS may include a synthetic resin substrate or a glass substrate. The circuit element layer DP-CL may include at least one insulating layer and a circuit element The circuit element may include a signal line, a driving circuit of a pixel, and the like. The circuit element layer DP-CL may be formed through a process of forming an insulating layer, a semiconductor layer, and a conductive layer by coating, deposition, or the like, and a process of patterning the insulating layer, the semiconductor layer, and the conductive layer by a photolithography process. The display element layer DP-LED may include at least a display element. The optical structure layer OSL may convert a color of the light provided from a display element. The optical structure layer OSL may include a structure for increasing a light control pattern and a light conversion efficiency.

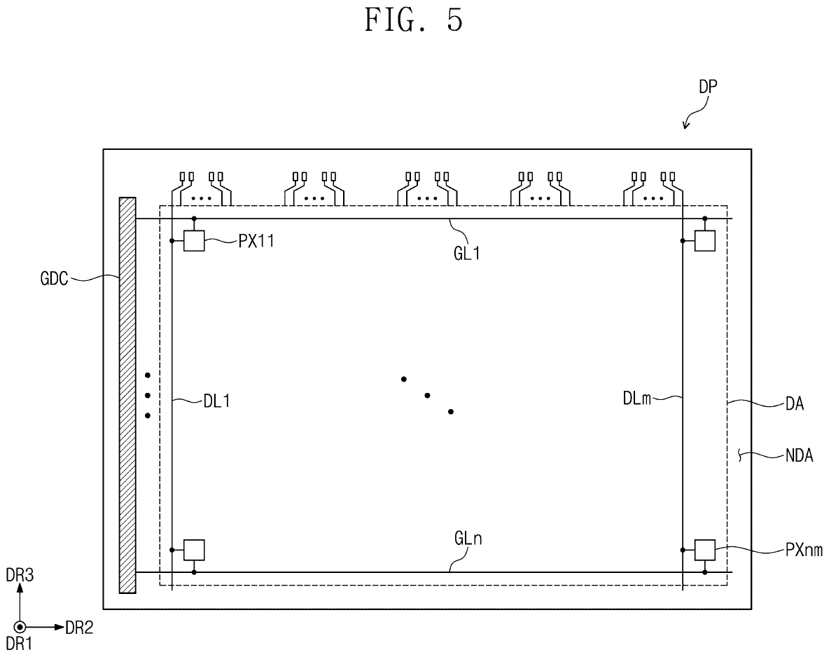

FIG. 5 is a plan view of a display panel according to an embodiment of the present disclosure.

Referring to FIG. 5, FIG. 5 illustrates a disposition relationship between signal lines GL1 to GLn and DL1 to DLm and pixels PX11 to PXnm, in a plan view. The signal lines GL1 to GLn and DL1 to DLm may include a plurality of gate lines GL1 to GLn and a plurality of data lines DL1 to DLm.

Each of the pixels PX11 to PXnm is connected to a corresponding one of the plurality of gate lines GL1 to GLn and a corresponding one of the plurality of data lines DL1 to DLm. Each of the pixels PX11 to PXnm may include a pixel driving circuit and a display element. More types of signal lines may be provided on the display panel DP depending on a configuration of the pixel driving circuit of each of the pixels PX11 to PXnm.

The gate driving circuit GDC may be integrated into the display panel DP through an oxide silicon gate driver circuit OSG or an amorphous silicon gate driver circuit (ASG) process.

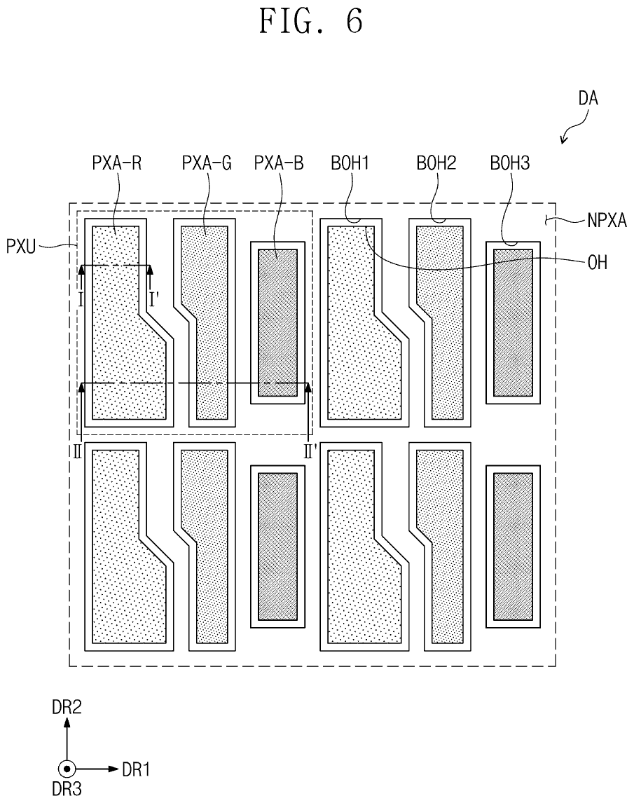

FIG. 6 is an enlarged plan view of a portion of a display panel according to an embodiment.

Referring to FIG. 6, a disposition relationship of a plurality of pixel areas disposed on the display area DA in the display panel DP (see FIG. 2) is illustrated. In an embodiment, three types of pixel areas PXA-R, PXA-G, and PXA-B illustrated in FIG. 6 may be repeatedly disposed on the entire display area DA (see FIG. 2). The pixel areas PXA-R, PXA-G, and PXA-B may be referred to as light emission areas.

In an embodiment, the electronic device ED (see FIG. 1) may include a first pixel area PXA-R, a second pixel area PXA-G, and a third pixel area PXA-B that emit light in different wavelength areas. The first to third pixel areas PXA-R, PXA-G, and PXA-B may be separated from each other without overlapping each other in a plan view.

The first pixel area PXA-R may emit light having an emission wavelength of 610 nanometers (nm) or more and 700 nm or less, the second pixel area PXA-G may emit light having an emission wavelength of 500 nm or more and 590 nm or less, and the third pixel area PXA-B may emit light having an emission wavelength of 410 nm or more and 480 nm or less.

In an embodiment, the first pixel area PXA-R may be a red pixel area that emits a red light, the second pixel area PXA-G may be a green pixel area that emits a green light, and the third pixel area PXA-B may be a blue pixel area that emits a blue light. However, embodiments are not limited thereto, and in an embodiment, the display area DA may further include a pixel area that emits a white light, in addition to the first to third pixel areas PXA-R, PXA-G, and PXA-B in another embodiment.

In an embodiment, one first pixel area PXA-R, one second pixel area PXA-G, and one third pixel area PXA-B may be used as a group to configure one pixel unit PXU. The arrangement of the pixel areas illustrated in FIG. 6 is exemplary, and one pixel unit PXU may further include a pixel area that emitting a light of another wavelength area, in addition to the first to third pixel areas. Furthermore, two or more of at least one of the first to third pixel areas may be included in one pixel unit PXU.

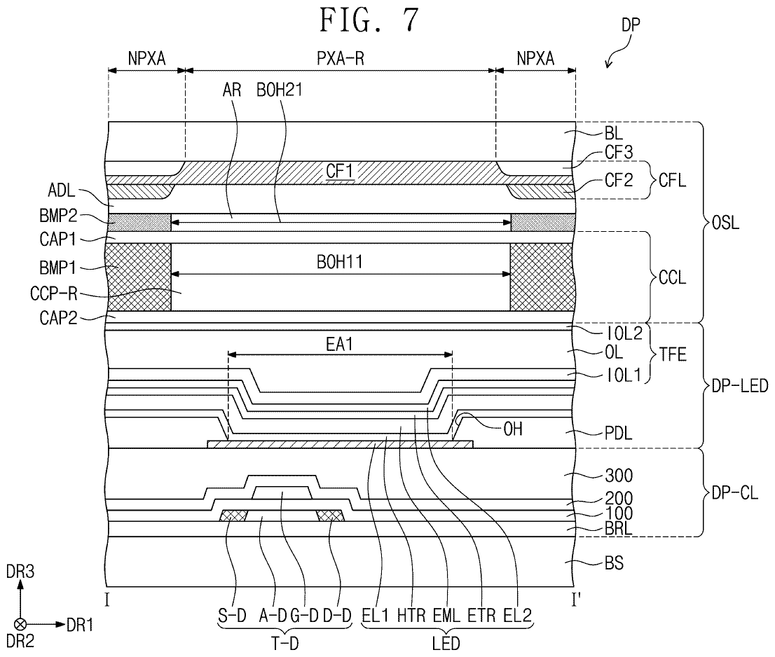

A non-pixel area NPXA is disposed around the first to third pixel areas PXA-R, PXA-G, and PXA-B. The non-pixel area NPXA may be referred to as a non-light emission area. The non-pixel area NPXA may be disposed to surround each of the first pixel area PXA-R, the second pixel area PXA-G, and the third pixel area PXA-B. The non-pixel area NPXA sets boundaries between the first to third pixel areas PXA-R, PXA-G, and PXA-B, and may prevent color mixing between the first to third pixel areas PXA-R, PXA-G, and PXA-B. In the non-pixel area NPXA, a structure that prevents color mixing between the first to third pixel areas PXA-R, PXA-G, PXA-B, for example, a pixel definition film PDL (see FIG. 7) or a bank BMP (see FIG. 7) may be disposed.

In an embodiment illustrated in FIG. 6, some of the first to third pixel areas PXA-R, PXA-G, and PXA-B may have a rectangular shape. The remaining ones of the first to third pixel areas PXA-R, PXA-G, and PXA-B may have a polygonal shape having a protrusion that protrudes from a rectangular shape. At least a portion of each of the first to third pixel areas PXA-R, PXA-G, and PXA-B may have a polygonal shape having a short side that extends along the first direction DR1 and a long side that extends along the second direction DR2. Extents of the first to third pixel areas PXA-R, PXA-G, and PXA-B may be set depending on light emitting colors. An extent of a pixel area that emits a blue light that is one of the main colors may be the smallest, and an extent of a pixel area that emitting a red light that is one of the main colors may be the largest. Furthermore, unlike this, an extent of a pixel area that emits a red light and an area of a pixel area that emits a green light may be substantially the same.

Although FIG. 6 illustrates first to third pixel areas PXA-R, PXA-G, and PXA-B having a rectangular or polygonal shape, the present disclosure is not limited thereto. Some of the first to third pixel areas PXA-R, PXA-G, and PXA-B in a plan view may have a polygonal shape (including a substantially polygonal shape) having a different shape. In an embodiment, the first to third pixel areas PXA-R, PXA-G, and PXA-B may have a rectangular shape (a substantially rectangular shape) having a rounded corner area or a polygonal shape (a substantially polygonal shape) having a rounded corner area in a plan view.

FIG. 7 is a cross-sectional view of a portion of a display panel, taken along line I-I′ of FIG. 6 according to an embodiment of the present disclosure.

Referring to FIG. 7, the display panel DP according to an embodiment may include a base substrate BS, a circuit element layer DP-CL that is disposed on the base substrate BS, and a display element layer DP-LED that is disposed on the circuit element layer DP-CL. In the specification, the base substrate BS, the circuit element layer DP-CL, and the display element layer DP-LED may be collectively referred to as a lower panel.

The base substrate BS may be a member that provides a reference surface, on which a component included in the circuit element layer DP-CL is disposed. In an embodiment, the base substrate BS may be a glass substrate, a metal substrate, a polymer substrate, or the like. However, embodiments are not limited thereto, and the base substrate BS may be an inorganic layer, a functional layer, or a composite material layer in another embodiment.

The base substrate BS may have a multi-layered structure. For example, the base substrate BS may have a three-layered structure including a polymer resin layer, an adhesion layer, and a polymer resin layer. In particular, the polymer resin layer may include a polyimide-based resin. In addition, the polymer resin layer may include at least one of acrylate-based resin, methacrylate-based resin, polyisoprene-based resin, vinyl-based resin, epoxy-based resin, urethane-based resin, cellulose-based resin, siloxane-based resin, polyamide-based resin, and perylene-based resin. In the meantime, “α” based resin in the specification may mean including the functional group of “α”.

The circuit element layer DP-CL may be disposed on the base substrate BS. The circuit element layer DP-CL may include a transistor T-D as a circuit element. As a driving circuit of the pixels PX11-PXnm (see FIG. 5) is designed, the configuration of the circuit element layer DP-CL may vary, and one transistor T-D is illustrated in FIG. 7 by way of example. Disposition relations of the active A-D, the source S-D, the drain D-D, and the gate G-D that constitute the transistor T-D are illustrated by way of example. The active A-D, the source S-D, and the drain D-D may be areas that are classified depending on a doping concentration or a conductivity of a semiconductor pattern.

The circuit element layer DP-CL may include a lower buffer layer BRL, a first insulation layer 100, a second insulation layer 200, and a third insulation layer 300 that are disposed on the base substrate BS. For example, the lower buffer layer BRL, the first insulation layer 100, and the second insulation layer 200 may be inorganic layers, and the third insulation layer 300 may be organic layers.

The display element layer DP-LED may include a light emitting element LED as a display element. The light emitting element LED may output a source light. In an embodiment, the source light may be a white light or a blue light. In an embodiment, the display element layer DP-LED may include an organic light emitting diode as a light emitting element. That is, the light emission layer EML included in the light emitting element LED may include an organic light emitting material as a light emitting material.

The light emitting element LED may include a first electrode EL1, a second electrode EL2, and a light emission layer EML that is disposed therebetween. In an embodiment, the display element layer DP-LED may include an organic light emitting diode as a light emitting element. In an embodiment of the present disclosure, the light emitting element may include a quantum dot light emitting diode. That is, the light emission layer EML included in the light emitting element LED may include an organic light emitting material as a light emitting material, or the light emission layer EML may include quantum dots as a light emitting material. Alternatively, in an embodiment, the display element layer DP-LED may include an ultra-small light emitting element that will be described later as a light emitting element. The ultra-small light emitting element may include, for example, a micro LED element and/or a nano LED element. The ultra-small light emitting element may be a light emitting element having a micro or nano-scale size and including an active layer disposed between the plurality of semiconductor layers.

The first electrode EL1 may be disposed on the third insulation layer 300. The first electrode EL1 may be directly or indirectly connected to the transistor T-D, and a connection structure between the first electrode EL1 and the transistor T-D is not illustrated in FIG. 7.

The display element layer DP-LED may include a pixel definition film PDL. For example, the pixel definition film PDL may be an organic layer. A light emission opening OH may be defined in the pixel definition film PDL. The light emission opening OH of the pixel definition film PDL may expose at least a portion of the first electrode EL1. In an embodiment, the first light emission area EA1 may be defined by the light emission opening OH.

A hole control layer HTR, the light emission layer EML, and an electron control layer ETR may overlap at least the first to third pixel areas PXA-R, PXA-B, and PXA-G (see FIG. 6) in a plan view. Each of the hole control layer HTR, the light emission layer EML, the electron control layer ETR, and the second electrode EL2 may be disposed in common in the first to third pixel areas PXA-R, PXA-B, AND PXA-G (see FIG. 6). Each of the hole control layer HTR, the light emission layer EML, the electron control layer ETR, and the second electrode EL2 that overlap the first to third pixel areas PXA-R, PXA-B, AND PXA-G (see FIG. 6) in a plan view may have an integral shape. However, the present disclosure is not limited thereto, and at least one of the hole control layer HTR, the light emission layer EML, and the electron control layer ETR may be formed to be separated from each of the first to third pixel areas PXA-R, PXA-B, AND PXA-G (see FIG. 6) in another embodiment. In an embodiment, the light emission layer EML may be patterned in the light emission opening OH to be separated from each of the first to third pixel areas PXA-R, PXA-B, AND PXA-G (see FIG. 6).

The hole control layer HBR may include a hole transport layer and may further include a hole injection layer.

The light emission layer EML may generate a third light that is a source light. The light emission layer EML may generate a blue light. The blue light may include a light having a wavelength of 410 nm to 480 nm. An emission spectrum of the blue light may have a maximum peak in a wavelength range of 440 nm to 460 nm.

The electron control layer ETR may include an electron transport layer, and may further include an electron injection layer.

The display element layer DP-LED may include a thin film encapsulation layer TFE that protects the second electrode EL2. The thin film encapsulation layer TFE may include an organic material or an inorganic material. The thin film encapsulation layer TFE may have a multi-layered structure, in which inorganic layers/organic layers are repeated. In an embodiment, the thin film encapsulation layer TFE may include a first encapsulation inorganic layer IOL1/an encapsulation organic layer OL/a second encapsulation inorganic layer IOL2. The first and second encapsulation inorganic layers IOL1/IOL2 may protect the light emitting element LED from external moisture, and the encapsulation organic layer OL may prevent a stamping defect of the light emitting element LED due to a foreign material introduced during a manufacturing process.

As illustrated in FIG. 7, an optical structural layer OSL may be disposed on the light emitting element LED. The optical structural layer OSL may include a light control layer CCL, a second bank BMP2, an adhesion layer ADL, a color filter layer CFL, and a base layer BL. The optical structural layer OSL may convert the source light into a light of a different wavelength. In the specification, the optical structural layer OSL may be referred to as an upper panel.

The light control layer CCL may be disposed on the display element layer DP-LED including the light emitting element LED. The light control layer CCL may include a first bank BMP1, a first light control pattern CCP-R, a first barrier layer CAP1, and a second barrier layer CAP2.

The first bank BMP1 may include a base resin and an additive. The base resin may be formed of various resin compositions that may generally be referred to as a binder. The additive may include a coupling agent and/or a photoinitiator. The additive may further include a dispersant.

The first bank BMP1 may include a black coloring agent for shielding light. The first bank BMP1 may include a black dye or a black pigment that is mixed with the base resin. In an embodiment, the black component may include carbon black, a metal, such as chromium, or an oxide thereof.

The first bank BMP1 may define a first bank opening BOH1 corresponding to the light emission opening OH. In a plan view, the first bank opening BOH1 overlaps the light emission opening OH in a plan view and has an extent/size that is larger than a size of the light emission opening OH. That is, the first bank opening BOH1 may have an extent/size that is larger than a size of the first light emission area EA1 defined by the light emission opening OH. Meanwhile, “corresponding” in the specification means that the two components overlap each other in the thickness direction DR3 of the display panel DP, and is not limited to the same extent.

A first light control pattern CCP-R may be disposed inside the first bank opening BOH1. The first light control pattern CCP-R may change optical properties of the source light.

The first light control pattern CCP-R may include quantum dots for changing the optical properties of the source light. The first light control pattern CCP-R may include a first quantum dot for converting the source light into light of a different wavelength. In the first light control pattern CCP-R that overlaps the first pixel area PXA-R in a plan view, the first quantum dot may convert the source light into a red light.

In the specification, a “quantum dot” may refer to a crystal of a semiconductor compound. Quantum dots may emit light having various emission wavelengths depending on a size of the crystal. The quantum dots may emit light having various emission wavelengths by adjusting a ratio of elements in the quantum dot compound.

A diameter of the quantum dot may be, for example, about 1 nm to 10 nm.

The quantum dots may be synthesized through a wet chemical process, an organometallic chemical deposition process, a molecular beam epitaxial process, or a similar process.

The wet chemical process is a method of growing quantum dot particle crystals after mixing an organic solvent and a precursor material. When the crystal is grown, the organic solvent may naturally act as a dispersant that is coordinated on the surface of the quantum dot crystal, and the growth of the crystal may be controlled. Accordingly, the wet chemical process is easier than the vapor deposition method, such as metal organic chemical vapor deposition (MOCVD) or molecular beam epitaxy (MBE), and the growth of quantum dot particles may be controlled through a low-cost process.

The core of the quantum dot may be selected from a group II-VI compound, a group III-V compound, a group III-VI compound, a group IV-VI compound, a group IV element, a group IV compound, and a combination thereof.

The II-VI group compound may be selected from the group consisting of a diatomic compound selected from the group consisting of CdSe, CdTe, CdS, ZnS, ZnSe, ZnTe, ZnO, HgS, HgSe, HgTe, MgSe, MgS, and mixtures thereof, a triatomic compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof, a four-element compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. Meanwhile, the II-VI semiconductor compound may further include a group I metal and/or a group IV element. The I-II-VI compound may be selected from CuSnS or CuZnS, and the II-IV-VI compound may be selected from ZnS or the like. The I-II-IV-VI group compound may be selected from the group consisting of Cu₂ZnSnS₂, Cu₂ZnSnS₄, Cu₂ZnSnSe₄, Ag₂ZnSnS₂, and mixtures thereof.

The III-VI group compound may include a diatomic compound, such as In₂S₃ and In₂Se₃, a triatomic compound, such as InGaS₃ and InGaSe₃, or any combination thereof.

The I-III-VI group compound may be selected from the group consisting of a triatomic compound selected from the group consisting of AgInS, AgInS₂, CuInS, CuInS₂, AgGaS₂, CuGaS₂, CuGaO₂, AgGaO₂, AgAlO₂, and mixtures thereof, or a four-element compound, such as AgInGaS₂, CuInGaS₂, and CuInGaS₂.

The III-V group compound may be selected from the group consisting of a diatomic compound selected from the group consisting of GaN, GaP, GaAs, GaSb, AlN, AlP, AlAs, AlSb, InN, InP, InAs, InSb, and mixtures thereof, a triatomic component selected from the group consisting of GaNP, GaNAs, GaNSb, GaPAs, GaPSb, AlNP, AlNAs, AlNSb, AlPSb, AlPSb, InGaP, InAlP, InNP, InNAs, InNSb, InPAs, InPSb, and mixtures thereof, and a four-element compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. Meanwhile, the group III-V compound may further include a group II metal. For example, InZnP and the like may be selected as the group III-II-V compound.

The IV-VI group compound may be selected from the group consisting of a diatomic component selected from the group consisting of SnS, SnSe, SnTe, PbS, PbSe, PbTe, and mixtures thereof; a triatomic component selected from the group consisting of SnSeS, SnSeTe, SnSTe, PbSeS, PbSeTe, PbSTe, SnPbS, SnPbSe, SnPbTe, and mixtures thereof; and a four-element compound selected from the group consisting of SnPbSSe, SnPbSeTe, SnPbSTe, and mixtures thereof.

An example of the group II-IV-V semiconductor compound may be a diatomic compound selected from the group consisting of ZnSnP, ZnSnP₂, ZnSnAs₂, ZnGeP₂, ZnGeAs₂, CdSnP₂, and CdGeP₂, and mixtures thereof.

The group IV element may be selected from the group consisting of Si, Ge, and mixtures thereof. The group IV compound may be a diatomic compound selected from the group consisting of SiC, SiGe, and mixtures thereof.

Each element included in the multi-element compound, such as the diatomic compound, the triatomic compound, and the four-element compound, may exist in the particles at a uniform or non-uniform concentration. That is, the chemical formula refers to the kind of elements included in the compound, and the ratio of elements in the compound may be different. For example, AgInGaS₂ may mean AgInxGa1—xS₂ (“x”is a real number between 0 and 1).

In this case, the diatomic compound, the triatomic compound, or the four-element compound may be present in the particle at a uniform concentration, or may be present in the same particle in a state, in which the concentration distribution is divided to be partially different. Furthermore, one quantum dot may have a core/shell structure that surrounds another quantum dot. In the core/shell structure, the concentration of the element that is present in the shell may have a concentration gradient, in which it decreases as it goes toward the core.

In some embodiments, the quantum dot may have a core-shell structure including a core including the above-described nanocrystal and a shell that surrounds the core. The shell of the quantum dot may serve as a protective layer for maintaining semiconductor properties by preventing chemical denaturation of the core and/or a charging layer for imparting electrophoretic properties to the quantum dots. The shell may have a single layer or multiple layers. Examples of the shell of the quantum dots may include an oxide of a metal or a non-metal, a semiconductor compound, or a combination thereof.

For example, an example of the metal or non-metal oxide may be a diatomic compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a triatomic compound, such as MgAl₂O₄, CoFe₂O₄, NiFe₂O₄, or CoMn₂O₄, but the present disclosure is not limited thereto.

Furthermore, an example of the semiconductor compound may include CdS, CdSe, CdTe, ZnS, ZnSe, ZnTe, ZnSeS, ZnTe, GaAs, GaP, GaSb, HgS, HgSe, HgTe, InAs, InP, InGaP, InSb, AlAs, AlP, AlSb, and the like, but the present disclosure is not limited thereto.

Quantum dots may have a full width of half maximum (FWHM) of an emission wavelength spectrum of about 45 nm or less, preferably about 40 nm or less, and more preferably about 30 nm or less, and in this range, a color purity or a color reproducibility may be improved. Furthermore, because the light emitted through the quantum dots is emitted in all directions, the viewing angle of the light may be improved.

Furthermore, the shape of quantum dots is not particularly limited to those commonly used in the art, but more specifically, spherical, pyramid-shaped, multi-arm, or cubic nanoparticles, nanotubes, nanowires, nanofibers, and nanofibers may be used.

Because quantum dots may adjust the energy band gap by adjusting the size of the quantum dot or the element ratio in the quantum dot compound, lights of various wavelength bands may be obtained from the quantum dot light emission layer. Accordingly, by using quantum dots (of different sizes or having different elemental ratios in the quantum dot compound) as described above, a light emitting element that emits light of various wavelengths may be implemented. Specifically, the size of the quantum dot or the elemental ratio in the quantum dot compound may be selected to emit red, green, and/or blue lights. Furthermore, the quantum dots may be configured to emit white light as lights of various colors are combined.

In an embodiment, a quantum dot included in the first light control pattern CCP-R that overlaps the first pixel area PXA-R in a plan view may have a red emission color. As the size of the particles of the quantum dot becomes smaller, light in the shorter wavelength area may be emitted. For example, the size of the particles of the quantum dots having the same core, which emit a green light, may be smaller than the size of the particles of the quantum dots that emit a red light. Furthermore, the size of the particles of the quantum dots having the same core, which emit a blue light, may be smaller than the size of the particles of the quantum dots that emit a green light. However, the embodiment is not limited thereto, and the size of the particles may be adjusted depending on a shell forming material and a shell thickness even in the quantum dots having the same core.

On the other hand, when the quantum dots have various emission colors, such as blue, red, and green, the quantum dots having different emission colors may have different core materials.

The first light control pattern CCP-R may further include a scatterer. The first light control pattern CCP-R may include a first quantum dot that converts the blue light into the red light, and a scatterer that scatters light.

The scatterer SP may be inorganic particles. For example, the scatterer may include at least one of TiO₂, ZnO, Al2O₃, SiO₂, and hollow silica. The scatterer may include any one of TiO₂, ZnO, Al2O₃, SiO₂, and hollow silica, or may include a mixture of two or more materials selected from TiO₂, ZnO, Al2O₃, SiO₂, and hollow silica.

The first light control pattern CCP-R may include a base resin that disperses the first quantum dot and the scatterer. The base resin is a medium, in which the first quantum dot and the scatterer are dispersed, and may be formed of various resin compositions that may be generally referred to as a binder. For example, the base resin may be an acrylic resin, a urethane resin, a silicone resin, an epoxy resin, or the like. The base resin may be a transparent resin.

In an embodiment, the first light control pattern CCP-R may be formed through an inkjet process. A liquid composition may be provided in the first bank opening BOH1. A composition that is polymerized through a thermal curing process or a photocurable process may be reduced in volume after curing.

The light control layer CCL may include a first barrier layer CAP1 that is disposed on one surface of the first light control pattern CCP-R. The first barrier layer CAP1 may serve to prevent penetration of moisture and/or oxygen (hereinafter, referred to as “moisture/oxygen”) and improve optical characteristics of the optical structure layer OSL by controlling a refractive index. The first barrier layer CAP1 may be disposed on one upper surface or one lower surface of the first light control pattern CCP-R to prevent the first light control pattern CCP-R from being exposed to moisture/oxygen, and particularly, may prevent a quantum dot included in the first light control pattern CCP-R from being exposed to moisture/oxygen. The first barrier layer CAP1 may also protect the first light control pattern CCP-R from an external impact.

In an embodiment, the first barrier layer CAP1 may be disposed to be spaced apart from the display element layer DP-LED with the first light control pattern CCP-R interposed therebetween. That is, the first barrier layer CAP1 may be disposed on the upper surface of the first light control pattern CCP-R.

In an embodiment, the light control layer CCL may include a second barrier layer CAP2 that is disposed between the first light control pattern CCP-R and the display element layer DP-LED. The first barrier layer CAP1 may cover an upper surface of the first light control pattern CCP-R, and the second barrier layer CAP2 may cover a lower surface of the first light control pattern CCP-R, which is adjacent to the display element layer DP-LED. Meanwhile, in the specification, an “upper surface” may be a surface that is located on an upper side with respect to the third direction DR3, and a “lower surface” may be a surface that is located on a lower side in the third direction DR3. Furthermore, the first barrier layer CAP1 and the second barrier layer CAP2 may cover not only the first light control pattern CCP-R but also one surface of the first bank BMP1.

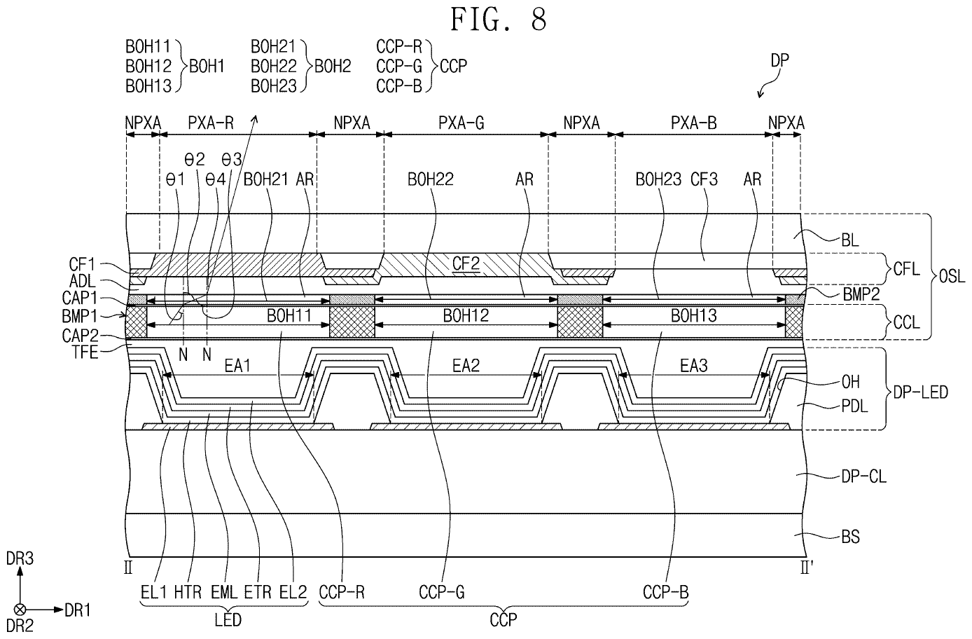

The second barrier layer CAP2 may be disposed directly on an upper portion of the thin film encapsulation layer TFE. The light control layer CCL may be disposed on the display element layer DP-LED and the thin film encapsulation layer TFE with the second barrier layer CAP2 interposed therebetween. The light control patterns CCP-R, CCP-G, and CCP-B (see FIG. 8) of the light control layer CCL may be formed on the second barrier layer CAP2 disposed on the thin film encapsulation layer TFE through a continuous process.

The first barrier layer CAP1 and the second barrier layer CAP2 may include an inorganic material. In the display panel DP of an embodiment, the first barrier layer CAP1 may include silicon oxynitride (SiON). Both the first barrier layer CAP1 and the second barrier layer CAP2 may include silicon oxynitride. However, the present disclosure is not limited thereto, and each of the first barrier layer CAP1 and the second barrier layer CAP2 may include silicon oxide (SiOx) or silicon nitride (SiNx) in another embodiment. In an embodiment, the first barrier layer CAP1 disposed on the first light control pattern CCP-R may include silicon oxynitride, and the second barrier layer CAP2 disposed under the first light control pattern CCP-R may include silicon oxide.

The second bank BMP2 may be disposed on the light control layer CCL. The second bank BMP2 may be disposed on the first barrier layer CAP1. The second bank BMP2 may include an organic material or an inorganic material. A thickness (e.g., a length in the third direction DR3) of the second bank BMP2 may be 3 μm to 5μm. As the second bank BMP2 has a constant thickness, a constant stepped structure may be formed on the first barrier layer CAP1.

A second bank opening BOH2 may be defined in the second bank BMP2. In a plan view, the first bank opening BOH1 and the second bank opening BOH2 may overlap each other. The second bank BMP2 may be disposed to have a specific thickness, and an air layer AR may be disposed in the second bank opening BOH2.

The adhesion layer ADL may be disposed on the second bank BMP2. The adhesion layer ADL may be disposed between the second bank BMP2 and the color filter layer CFL. An upper surface of the adhesion layer ADL may contact a lower surface of the color filter layer CFL, and a lower surface of the adhesion layer ADL may contact an upper surface of the second bank BMP2. A thickness (e.g., a length in the third direction DR3) of the adhesion layer ADL may be 3μm to 5μm.

The adhesion layer ADL may function as an impact absorbing member between the light control layer CCL and the color filter layer CFL. In an embodiment, the adhesion layer ADL may perform an impact absorbing function and the like, and may increase a strength of the display panel DP. The adhesion layer ADL may be formed from a polymer resin. For example, the adhesion layer ADL may include a photocurable resin or a thermophotovoltaic resin. The adhesion layer ADL may include acrylate or epoxide. A transition temperature of the adhesion layer ADL may be 50 degrees Celsius (° C.) to 80 degrees Celsius. A curing temperature of the adhesion layer ADL may be 80 degrees Celsius to 100 degrees Celsius.

The transition temperature and the curing temperature of the adhesion layer ADL may be higher than a room temperature (for example, 15° C. to 25° C.). The process of coupling the upper panel and the lower panel may be performed at a room temperature. When the transition temperature and the curing temperature of the adhesion layer ADL are higher than a room temperature, a phase transition or curing phenomenon (a phenomenon, in which physical properties of the adhesion layer ADL are rapidly changed) during the inter-panel coupling process, may be removed or reduced. Accordingly, because the physical properties of the adhesion layer ADL are not changed rapidly, the process of coupling the upper and lower panels may be normally performed. A reliability of the process of coupling the upper and lower panels may be improved.

A color filter layer CFL may be disposed on the light control layer CCL. The color filter layer CFL may be disposed on the second bank BMP2. The color filter layer CFL may include at least one color filter. The color filter may transmit light of a specific wavelength range, and may shield light outside the corresponding wavelength range. A first color filter CF1 corresponding to the first pixel area PXA-R may transmit a red light, and may shield a green light and a blue light.

The first color filter CF1 may include a base resin, and a dye and/or a pigment that is dispersed in the base resin. The base resin is a medium, in which the dye and/or the pigment is dispersed, and may be formed of various resin compositions that may be generally referred to as a binder.

The first color filter CF1 may have a uniform thickness in the first pixel area PXA-R. The light that is converted from the source light, which is the blue light, to the red light through the first light control pattern CCP-R may be provided to the outside with a uniform luminance in the first pixel area PXA-R.

In an embodiment, the display panel DP may further include a base layer BL that is disposed on the color filter layer CFL. The base layer BL may be a member that provides a reference surface, on which the color filter layer CFL and the light control layer CCL are disposed. The base layer BL may be a glass substrate, a metal substrate, a plastic substrate, or the like. However, an embodiment is not limited thereto, and the base layer BL may be an inorganic layer, an organic layer, or a composite material layer. Furthermore, unlike the illustration, the base layer BL may be omitted in an embodiment.

Although not illustrated, a reflection prevention layer may be disposed on the base layer BL. The reflection prevention layer may be a layer that reduces a reflectance of external light that is input from the outside. The reflection prevention layer may be a layer that selectively transmits light emitted from the display panel DP. In an embodiment, the reflection prevention layer may be a single layer including a dye and/or a pigment that is dispersed in the base resin. The reflection prevention layer may be provided as a one continuous layer that entirely overlaps the entire first to third pixel areas PXA-R, PXA-G, PXA-B in a plan view (see FIG. 6).

The reflection prevention layer may not include a polarizing layer. Accordingly, the light that passes through the reflection prevention layer and is input to the display element layer DP-LED may be unpolarized light. The display element layer DP-LED may receive light that is not polarized from an upper side of the reflection prevention layer.

FIG. 8 is a cross-sectional view illustrating a portion of a display panel, taken along line II-II′ of FIG. 6 according to an embodiment of the present disclosure.

Referring to FIG. 8, the display panel DP may include a base substrate BS, a circuit element layer DP-CL that is disposed on the base substrate BS, and an optical structure layer OSL. The circuit element layer DP-CL may include an insulating layer, a semiconductor pattern, a conductive pattern, a signal line, and the like. An insulating layer, a semiconductor layer, and a conductive layer may be formed on the base substrate BS through a coating or deposition process. Afterward, the insulating layer, the semiconductor layer, and the conductive layer may be selectively patterned through a plurality of photolithography processes. Afterward, the semiconductor pattern, the conductive pattern, and the signal line included in the circuit element layer DP-CL may be formed. In an embodiment, the circuit element layer DP-CL may include a transistor, a buffer layer, and a plurality of insulating layers.

The light emitting element LED according to an embodiment may include a first electrode EL1, a second electrode EL2 facing the first electrode EL1, and a light emission layer EML that is disposed between the first electrode EL1 and the second electrode EL2. The light emission layer EML may include an organic light emitting material or a quantum dot as a light emitting material. The light emitting element LED may further include a hole control layer HTR and an electron control layer ETR. Meanwhile, although not illustrated, the light emitting element LED may further include a capping layer (not illustrated) that is disposed on the second electrode EL2.

The pixel definition film PDL is disposed on the circuit element layer DP-CL and may cover a portion of the first electrode EL1. A light emission opening OH may be defined in the pixel definition film PDL. The light emission opening OH of the pixel definition film PDL may expose at least a portion of the first electrode EL1. The light emission areas EA1, EA2, and EA3 may be defined to correspond to a partial area of the first electrode EL1, which is exposed by the light emission opening OH.

The display element layer DP-LED may include a first light emission area EA1, a second light emission area EA2, and a third light emission area EA3. The first light emission area EA1, the second light emission area EA2, and the third light emission area EA3 may be areas that are distinguished by the light emission opening OH. The first light emission area EA1, the second light emission area EA2, and the third light emission area EA3 may correspond to the first pixel area PXA-R, the second pixel area PXA-G, and the third pixel area PXA-B, respectively.

The light emission areas EA1, EA2, and EA3 may overlap the pixel areas PXA-R, PXA-B, and PXA-G in a plan view. In a plan view, the extents of the pixel areas PXA-R, PXA-B, and PXA-G distinguished by the color filters CF1, CF2, and CF3 may be substantially the same as the extents of the light emission areas EA1, EA2, and EA3 distinguished by the pixel definition film PDL.

In the light emitting element LED, the first electrode EL1 may be disposed on the circuit element layer DP-CL. The first electrode EL1 may be an anode or a cathode. Furthermore, the first electrode EL1 may be a pixel electrode. The first electrode EL1 may be a transmissive electrode, a transflective electrode, or a reflective electrode.

The hole control layer HTR may be disposed between the first electrode EL1 and the light emission layer EML. The hole control layer HTR may include at least one of a hole injection layer, a hole transport layer, and an electron blocking layer. The hole control layer HTR may be disposed as a common layer to overlap the entire pixel definition film PDL that distinguishes the light emission areas EA1, EA2, and EA3 and the light emission areas EA1, EA2 and EA3. However, embodiments are not limited thereto, and the hole control layer HTR may be patterned to be disposed to be separated in correspondence to each of the light emission areas EA1, EA2, and EA3 in another embodiment.

The light emission layer EML is disposed on the hole control layer HTR. In an embodiment, the light emission layer EML may be provided as a common layer to overlap the light emission areas EA1, EA2, and EA3, and the entire pixel definition film PDL that distinguishes the light emission areas EA1, EA2, and EA3 from each other. In an embodiment, the light emission layer EML may emit a blue light. The light emission layer EML may overlap the entire hole control layer HTR and the electron control layer ETR in a plan view.

However, an embodiment is not limited thereto, and in another embodiment, the light emission layer EML may be disposed in the light emission opening OH. That is, the light emission layer EML may be formed to be separated to correspond to the light emission areas EA1, EA2, and EA3 distinguished by the pixel definition film PDL. The light emission layer EML formed to be separated to correspond to the light emission areas EA1, EA2, and EA3 may emit a blue light or may emit light in different wavelength areas.

The light emission layer EML may have a single layer formed of a single material, a single layer formed of a plurality of different materials, or a multi-layered structure having a plurality of layers formed of a plurality of different materials. The light emission layer EML may include a fluorescent or phosphorescent material. In the light emitting element of an embodiment, the light emission layer EML may include an organic light emitting material, a metal organic complex, or a quantum dot as a light emitting material. Meanwhile, in FIGS. 7 and 8, a light emitting element LED including one light emission layer EML is illustrated by way of example, but in an embodiment, the light emitting element LED may include a plurality of light emission stacks each including at least one light emission layer.

The optical structure layer OSL may include a first bank BMP1 and a second bank BMP2. The first bank BMP1 may define a first bank opening BOH1. The second bank BMP2 may define a second bank opening BOH2. A plurality of first bank openings BOH1 and a plurality of second bank openings BOH2 may be defined.

A first light control pattern CCP-R, a second light control pattern CCP-G, and a third light control pattern CCP-B may be disposed in the first to third bank openings BHO1, BOH2, and BOH3.

The light control patterns CCP-R, CCP-G, and CCP-B may be spaced apart from each other. The light control patterns CCP-R, CCP-G, and CCP-B may be disposed to be spaced apart from each other by the first bank BMP1. Although FIG. 8 illustrates that the first bank BMP1 has a rectangular shape on a cross section and does not overlap the light control patterns CCP-R, CCP-G, and CCP-B in a plan view, edges of at least some of the light control patterns CCP-R, CCP-G, and CCP-B may overlap the first bank BMP1. For example, an edge of the third light control pattern CCP-B may be disposed to overlap the first bank BMP1 in a plan view. The first bank BMP1 may have a trapezoidal shape on a cross section. The first bank BMP1 may have a shape, of which a width on a cross section increases as it becomes closer to the display element layer DP-LED.

The light control pattern CCP-R, CCP-G, and CCP-B may be a part that converts a wavelength of the light provided from the display element layer DP-LED or transmits the light provided.

The light control layer CCL may include a first light control pattern CCP-R that provides a red light that is the first light, a second light control pattern CCP-G that provides a green light that is the second light, and a third light control pattern CCP-B that provides a blue light that is the third light. The light control layer CCL may include a first light control pattern CCP-R that converts the source light provided from the light emitting element LED into the first light, a second light control pattern CCP-G that converts the source light into the second light, and a third light control pattern CCP-B that transmits the source light. At least some of the light control patterns CCP-R, CCP-G, and CCP-B may include quantum dots that convert the source light into light of a specific wavelength.

Some of the light control patterns CCP-R, CCP-G, and CCP-B may be formed through an inkjet process. In an embodiment, the first light control pattern CCP-R and the second light control pattern CCP-G may be formed through an inkjet process. A liquid ink composition may be provided to an interior of each of the first bank opening BOH1 and the second bank opening BOH2, and the provided ink composition may be polymerized through a thermal curing process or a photo-curing process to form the first light control pattern CCP-R and the second light control pattern CCP-G. The remaining ones of the light control patterns CCP-R, CCP-G, and CCP-B may be formed through a photoresist process. In an embodiment, the third light control pattern CCP-B may be formed through a photoresist process. After the photoresist composition is provided in at least (1-3)-th bank opening BOH13, the provided photoresist composition may be cured to form a third light control pattern CCP-B.

The light control pattern CCL may further include a scatterer. The first light control pattern CCP-R may include a first quantum dot and a scatterer, the second light control pattern CCP-G may include a second quantum dot and a scatterer, and the third light control pattern CCP-B may include a scatterer without quantum dots. Each of the first light control pattern CCP-R, the second light control pattern CCP-G, and the third light control pattern CCP-B may further include a base resin that disperses quantum dots and scatterers. Meanwhile, because the third light control pattern CCP-B is formed through a photoresist process as will be described later, the third light control pattern CCP-B may include a photosensitive resin.

A plurality of second bank openings BOH21, BOH22, and BOH23 may overlap the first bank openings BOH11, BOH12, and BOH13 in a plan view. The first bank openings BOH11, BOH12, and BOH13 arranged in the first direction DR1 may include a (1-1)-th bank opening BOH11, a (1-2)-th bank opening BOH12, and a (1-3)-th bank opening BOH13. The second bank openings BOH21, BOOH22, and BOH23 may include a (2-1)-th bank opening BOH21, a (2-2)-th bank opening BOH22, and a (2-3)-th bank opening BOH23 arranged in the first direction DR1.

In a plan view, the (1-1)-th bank opening BOH11 and the (2-1)-th bank opening BOH21 may overlap each other. In a plan view, the (1-2)-th bank opening BOH12 and the (2-2)-th bank opening BOH22 may overlap each other. In a plan view, the (1-3)-th bank opening BOH13 and the (2-3)-th bank opening BOH23 may overlap each other.

An air layer AR may be disposed in the second bank openings BOH21, BOH22, and BOH23. The air layer AR may be disposed between the light control layer CCL and the color filter layer CFL. The air layer AR may be disposed on the light control layer CCL to block the light control patterns CCP-R, CCP-G, and CCP-B from being exposed to moisture/oxygen. Furthermore, the air layer AR may be disposed between the light control patterns CCP-R, CCP-G, and CCP-B and the color filters CF1, CF2, and CF3 to increase a light extraction efficiency, or may function as an optical functional layer, for example, to prevent reflected light from being input to the light control layer CCL. The air layer AR may have a smaller refractive index compared to an adjacent layer (e.g., light control pattern CCP, adhesion layer ADL, color filter layer CFL, base layer BL, etc.).

Hereinafter, a light reflecting operation for the light control pattern CCP and the air layer disposed at the center thereof will be described. A normal line “N” illustrated in FIG. 8 may be defined as a line that extends in the third direction DR3 that is perpendicular to a horizontal plane. Hereinafter, an incident angle and a refraction angle are defined with respect to the normal line “N”.

Light may travel from the light control pattern CCP to the air layer AR. The light that travels from the light control pattern CCP to the air layer AR may be refracted due to a refractive index difference between the light control pattern CCP and the air layer AR. Because the refractive index of the air layer AR is lower than the refractive index of the light control pattern CCP, a refractive angle θ2 may be greater than an incident angle θ1 when the light travels from the light control pattern CCP to the air layer AR. Accordingly, substantially, the light may be diffused in the air layer AR.

The light may travel from the air layer AR to the adhesion layer ADL, the color filter layer CFL, and the base layer BL. Because the refractive indexes of the adhesion layer ADL, the color filter layer CFL, and the base layer BL are different from the refractive index of the air layer AR, the light may be refracted when the light travels from the air layer AR to the adhesion layer ADL, the color filter layer CFL, and the base layer BL.

Because the refractive indexes of the adhesion layer ADL, the color filter layer CFL, and the base layer BL are higher than the refractive index of the air layer AR, a refractive angle θ4 may be lower than an incident angle θ3 when the light travels from the air layer AR to the adhesion layer ADL, the color filter layer CFL, and the base layer BL. Accordingly, a straightness of the light may be substantially improved so that the light may be condensed. Because the light is condensed and emitted through the base layer BL, a light emission efficiency may be improved.

Accordingly, the air layer AR is disposed as a low refractive index layer between the light control pattern CCP and the color filter layer CFL, so that the light emission efficiency may be improved. The low refractive index layer may be partitioned by the second bank BMP2 and may be more easily combined with the color filter layer CFL by the adhesion layer ADL.

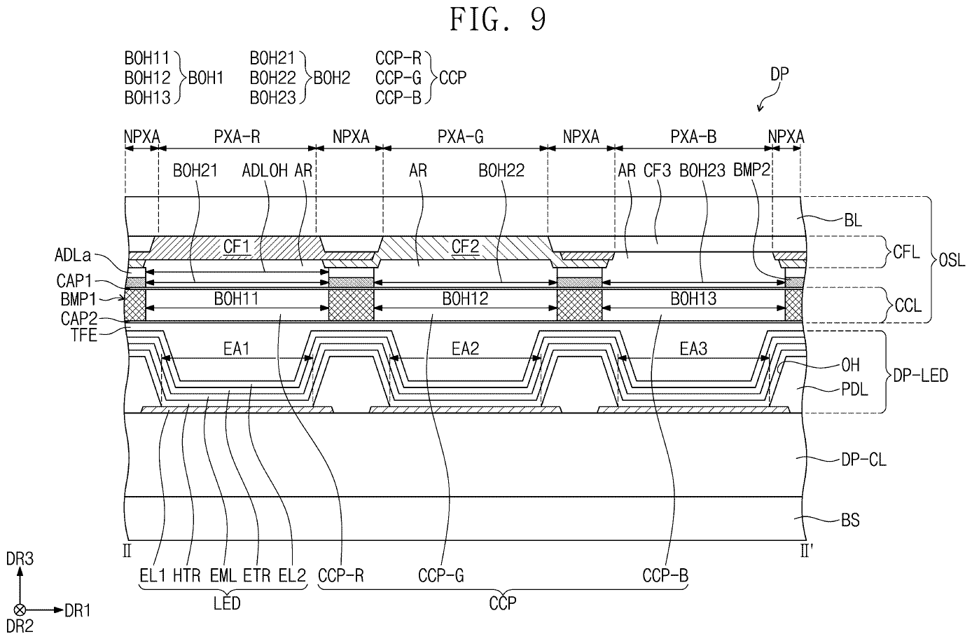

FIG. 9 is a cross-sectional view illustrating a portion of a display panel, taken along line II-II′ of FIG. 6 according to an embodiment of the present disclosure.

Referring to FIG. 9, in a plan view, an opening ADLOH that overlaps the second bank opening BOH2 may be defined in the adhesion layer ADLa. In a plan view, the adhesion layer ADLa may overlap the second bank BMP2, and may not overlap the first bank opening BOH1 and the second bank opening BOH2. That is, the opening ADLOH defined in the adhesion layer ADLa may overlap the first bank opening BOH1 and the second bank opening BOH2 in a plan view. An air layer AR may be disposed in the opening ADLOH. A plurality of opening ADLOH may be defined in the adhesion layer ADLa, and an air layer AR may be disposed in the openings ADLOH.

The air layer AR may be disposed in the second bank opening BOH2 and the opening ADLOH. The light may travel from the light control pattern CCP to the air layer AR disposed in the second bank opening BOH2 and the opening ADLOH. As described above with reference to FIG. 8, the light may travel from the light control pattern CCP to the air layer AR so that the light may be diffused in the air layer AR. When the light travels from the air layer AR to the upper panel, light may be refracted due to a difference in refractive indexes between the air layer AR and the upper panel. Due to the difference in the refractive indexes between the air layer AR and the upper panel, a straightness of light may be improved, so that the light may be condensed and the light emission efficiency may be improved.

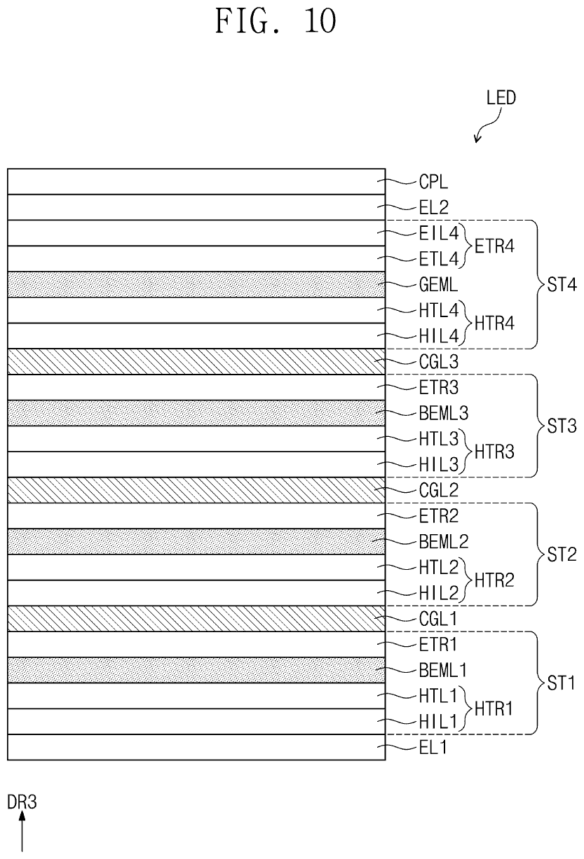

FIG. 10 is a cross-sectional view of a light emitting element according to an embodiment of the present disclosure. In FIG. 10, unlike the light emitting element illustrated in FIGS. 7 and 8, a light emitting element LED including a plurality of light emission stacks ST1, ST2, ST3, and ST4 is illustrated by way of example.

Referring to FIG. 10, the light emitting element LED according to an embodiment may include a first electrode EL1, a second electrode EL2 that faces the first electrode EL1, and first to fourth light emission stacks ST1, ST2, ST3, and ST4 that are disposed between the first electrode EL1 and the second electrode EL2. Meanwhile, although FIG. 5 illustrates that the light emitting element LED includes four light emission stacks by way of example, the number of light emission stacks included in the light emitting element LED may be less than or more than four.

The light emitting element LED may include first to third charge generating layers CGL1, CGL2, and CGL3 that are disposed between the first to fourth light emission stacks ST1, ST2, ST3, and ST4.

When a voltage is applied, each of the first to third charge generating layers CGL1, CGL2, and CGL3 may form a complex through an oxidation-reduction reaction to generate electric charges (electrons and holes). Thereafter, the first to third charge generating layers CGL1, CGL2, and CGL3 may provide the generated electric charges to the adjacent stacks ST1, ST2, ST3, and ST4, respectively. The first to third charge generating layers CGL1, CGL2, and CGL3 may increase an efficiency of current generated in the adjacent stacks ST1, ST2, ST3, and ST4 by multiple times, and may serve to adjust a balance of electric charges between the adjacent stacks ST1, ST2, ST3, and ST4.

Each of the first to third charge generating layers CGL1, CGL2, and CGL3 may include an n-type layer and a p-type layer. The first to third charge generating layers CGL1, CGL2, and CGL3 may have structures, in which an n-type layer and a p-type layer are joined to each other. However, the present disclosure is not limited thereto, and the first to third charge generating layers CGL1, CGL2, and CGL3 may include only one of an n-type layer and a p-type layer in another embodiment. The n-type layer may be a charge generating layer that provides electrons to an adjacent stack. The n-type layer may be a layer obtained by doping an n-dopant with a base material. The p-type layer may be a charge generating layer that provides holes to an adjacent stack.

In an embodiment, a thickness of each of the first to third charge generating layers CGL1, CGL2, and CGL3 may be 1 angstrom (Å) to 150 angstroms (Å). A concentration of the n-dopant doped into the first to third charge generating layers CGL1, CGL2, and CGL3 may be 0.1% or more and 3% or less, and specifically 1% or less. When the concentration is less than 0.1%, effects of the first to third charge generating layers CGL1, CGL2, and CGL3, in which electric charges adjust their balance, may hardly occur. When the concentration is greater than 3%, the light efficiency of the light emitting element OLED may be reduced.

Each of the first to third charge generating layers CGL1, CGL2, and CGL3 may include a charge generating compound consisting of an arylamine-based organic compound, a metal, an oxide of the metal, a carbide, a fluoride, or a mixture thereof. For example, the arylamine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The oxide, carbide, and fluoride of the metal may include Re₂O₇, MoO₃, V₂O₅, WO₃, TiO₂, Cs₂CO₃, BaF, LiF, or CsF. However, materials of the first to third charge generating layers CGL1, CGL2, and CGL3 are not limited to the above examples.

Each of the first to fourth light emission stacks ST1, ST2, ST3, and ST4 may include a light emission layer. The first light emission stack ST1 may include a first light emission layer BEML1, the second light emission stack ST2 may include a second light emission layer BEML2, the third light emission stack ST3 may include a third light emission layer BEML3, and the fourth light emission stack ST4 may include a fourth light emission layer GEML. Some of the light emission layers included in the first to fourth light emission stacks ST1, ST2, ST3, and ST4 may emit substantially the same color light, and some of the light emission layers may emit different color light.

In an embodiment, the first to third light emission layers BEML1, BEML2, and BEML3 of the first to third light emission stacks ST1, ST2, and ST3 may emit substantially the same first color light. For example, the first color light may be a blue light that is the above-described source light. A wavelength range of the light output by the first to third light emission layers BEML1, BEML2, and BEML3 may be about 420 nm to 480 nm.

The fourth light emission layer GEML of the fourth light emission stack ST4 may output a second color light that is different from the first color light. For example, the second color light may be a green light. A wavelength range of the light output by the fourth light emission layer GEML may be about 520 nm to 600 nm.

The light emitting element LED may output the light from the first electrode EL1 toward the second electrode EL2. In the light emitting element LED according to an embodiment, each of a plurality of stacks ST1, ST2, ST3, and ST4 may include a hole transport area HTR1, HTR2, HTR3, and HTR4 and an electron transport area ETR1, ETR2, ETR3, and ETR4. The hole transport areas HTR1, HTR2, HTR3, and HTR4 may deliver the holes provided from the first electrode EL1 or the charge generating layer CGL3 to the light emission layer. The electron transport areas ETR1, ETR2, ETR3, and ETR4 may deliver the electrons provided from the second electrode EL2 or the charge generating layer CGL1, CGL2, and CGL3 to the light emission layer.

The light emitting element LED of an embodiment illustrates, by way of example, a structure, in which the hole transport areas HTR1, HTR2, HTR3, and HTR4 are disposed under the light emission layers BEML-1, BEML-2, BEML-3, and GEML included in the plurality of stacks ST1, ST2, ST3, and ST4 and the electron transport areas ETR1, ETR2, ETR3, and ETR4 are disposed on the light emission layers BEML-1, BEML-2, BEML-3, and GEML included in the plurality of stacks ST1, ST2, ST3, and ST4, with respect to a direction, in which the light is output. That is, the light emitting element LED according to an embodiment may have a forward element structure. However, the present disclosure is not limited thereto, and it may have an inverted element structure, in which the electron transport areas ETR1, ETR2, ETR3, and ETR4 are disposed under the light emission layers BEML-1, BEML-2, BEML-3, and GEML included in the plurality of stacks ST1, ST2, ST3, and ST4, and the hole transport areas HTR1, HTR2, HTR3, and HTR4 are disposed on the light emission layers BEML-1, BEML-2, BEML-3, and GEML included in the plurality of stacks ST1, ST2, ST3, and ST4, with respect to the direction, in which the light is output.

Each of the hole transport areas HTR1, HTR2, HTR3, and HTR4 may include a hole transport layer HIL1, HIL2, HIL3, and HIL4 and a hole transport layer HTL1, HTL2, HTL3, and HTL4 disposed on the hole injection layer HIL1, HIL2, HIL3, and HIL4. The hole transport layers HTL1, HTL2, HTL3, and HTL4 may contact a lower surface of the light emission layer. However, the present disclosure is not limited thereto, and the hole transport areas HTR1, HTR2, HTR3, and HTR4 may further include a hole-side additional layer that is disposed on the hole transport layers HTL1, HTL2, HTL3, and HTL4 in another embodiment. The hole-side additional layer may include at least one of a hole buffer layer, an auxiliary light emission layer, and an electron blocking layer. The hole buffer layer may be a layer that compensates for a resonance distance depending on a wavelength of light emitted from the light emission layer to increase the light emission efficiency. The electron blocking layer may be a layer that functions to prevent electron injection from the electron transport area to the hole transport area.

The electron transport areas ETR1, ETR2, ETR3, and ETR4 may include an electron transport layer. The electron transport areas ETR1, ETR2, ETR3, and ETR4 may further include an electron injection layer that is disposed on the electron transport layer. For example, the fourth electron transport area ETR4 included in the fourth light emission stack ST4 may further include a fourth electron injection layer EIL4 that is disposed on the fourth electron transport layer ETL4. The electron transport areas ETR1, ETR2, ETR3, and ETR4 may further include an electron-side additional layer that is disposed between the electron transport layer and the light emission layers. The electron-side additional layer may include at least one of an electron buffer layer and a hole blocking layer.

In the light emitting element LED according to an embodiment, the first electrode EL1 may be a reflective electrode. For example, the first electrode EL1 may include Ag, Mg, Cu, Al, Pt, Pd, Au, Ni, Nd, Ir, Cr, Li, Ca, LiF/Ca, LiF/Al, Mo, Ti, W, In, Zn, Sn, or a compound or a mixture thereof (e.g., a mixture of Ag and Mg) that has a high reflectance. Alternatively, the first electrode EL1 may be a multi-layered structure including a reflective film formed of the above materials, and a transparent conductive film formed of indium tin oxide (ITO), indium zinc oxide (IZO), zinc oxide (ZnO), indium tin zinc oxide (ITZO), and the like. For example, the first electrode EL1 may have a two-layered structure of ITO/Ag and a three-layered structure of ITO/Ag/ITO, but the present disclosure is not limited thereto. Furthermore, embodiments are not limited thereto, and the first electrode EL1 may include the above-described metal materials, a combination of two or more metal materials selected from the above-described metal materials, an oxide of the above-described metal materials, or the like. A thickness of the first electrode EL1 may be about 70 nm to about 1000 nm. For example, the thickness of the first electrode EL1 may be about 100 nm to about 300 nm.

In the light emitting element LED according to an embodiment, each of the hole transport areas HTR1, HTR2, HTR3, and HTR4 may have a single layer formed of a single material, a single layer formed of a plurality of different materials, or a multi-layered structure having a plurality of layers formed of a plurality of different materials.

Each of the hole transport areas HTR1, HTR2, HTR3, and HTR4 may be formed by using various methods, such as vacuum deposition, spin coating, casting, a Langmuir-Blodgett (LB) method, inkjet printing, laser printing, and laser induced thermal imaging (LITI).

Each of the hole transport areas HTR1, HTR2, HTR3, and HTR4 may include phthalocyanine compounds such as copper phthalocyanine, DNTPD(N1,N1′-([1,1′-biphenyl]-4,4′-diyl)bis(N1-phenyl-N4,N4-di-m-tolylbenzene-1,4-diamine)), m-MTDATA(4,4′,4″-[tris(3-methylphenyl)phenylamino]triphenylamine), TDATA(4,4′4″-Tris(N,N-diphenylamino)triphenylamine), 2-TNATA(4,4′,4″-tris[N(2-naphthyl)-N-phenylamino]-triphenylamine), PEDOT/PSS (Poly(3,4-ethylenedioxythiophene)/Poly(4-styrenesulfonate)), PANI/DBSA (Polyaniline/Dodecylbenzenesulfonic acid), PANI/CSA(Polyaniline/Camphor sulfonicacid), PANI/PSS(Polyaniline/Poly(4-styrenesulfonate)), NPB(N,N′-di(naphthalene-l-yl)-N,N′-diphenyl-benzidine), polyether ketone (TPAPEK) containing triphenylamine, 4-Isopropyl-4′-methyldiphenyliodonium [Tetrakis(pentafluorophenyl)borate], and HATCN (dipyrazino[2,3-f: 2′,3′-h] quinoxaline-2 ,3,6,7,10,11-hexacarbonitrile).

Each of the hole transport areas HTR1, HTR2, HTR3, and HTR4 may include carbazole-based derivatives, such as N-phenylcarbazole and polyvinylcarbazole, fluorene-based derivatives, triphenylamine-based derivatives, such as TPD(N,N′-bis(3-methylphenyl)-N,N′-diphenyl-[1,1-biphenyl]-4,4′-diamine), TCTA(4,4′,4″-carbazolyl) triphenylamine, NDP (N,N′-di(naphthalene-l-yl)-N,N′-diphenyl-benzidine), TAPC(4,4′-Bis[N,N-bis(4-methylphenyl)benzenamine], HMTPD(4,4′-Bis[N,N′-(3-tolyl)amino]-3,3′-dimethylbiphenyl), mCP(1,3-Bis(N-carbazolyl)benzene), and the like.

Furthermore, each of the hole transport areas HTR1, HTR2, HTR3, and HTR4 may include CzSi (9-(4-tert-Butylphenyl)-3,6-bis(triphenylsilyl)-9H-carbazole), CCP (9-phenyl-9H-3,9′-bicarbazole), or mDCP (1,3-bis(1,8-dimethyl-9H-carbazol-9-yl)benzene).

The hole transport areas HTR1, HTR2, HTR3, and HTR4 may include compounds of the above-described hole transport areas in at least one of the hole injection layers HIL1, HIL2, HIL3, and HIL4, the hole transport layers HTL1, HTL2, HTL3, and HTL4, and the hole-side additional layer.

The thickness of each of the hole transport areas HTR1, HTR2, HTR3, and HTR4 may be about 10 to 1000 nm, for example, about 10 to 500 nm. The thickness of each of the hole injection layers HIL1, HIL2, HIL3, and HIL4 may be, for example, about 5 to 100 nm. The thickness of each of the hole transport layers HTL1, HTL2, HTL3, and HTL4 may be about 5 to 100 nm. When the hole transport areas HTR1, HTR2, HTR3, and HTR4 include the hole side additional layer, a thickness of the hole side additional layer may be about 1 to 100 nm. When the thicknesses of the hole transport areas HTR1, HTR2, HTR3, and HTR4 and the layers included therein satisfy the above-described range, a satisfactory degree of hole transport characteristics may be obtained with no substantial increase in the driving voltage.

Each of the hole transport areas HTR1, HTR2, HTR3, and HTR4 may further include a charge generating material to improve a conductivity, in addition to the above-described materials. The charge generating material may be uniformly or non-uniformly dispersed in the hole transport areas HTR1, HTR2, HTR3, and HTR4. The charge generating material may be, for example, a p-type dopant. The p-type dopant may include at least one of a halogenated metal compound, a quinone derivative, a metal oxide, and a cyano group-containing compound, but the present disclosure is not limited thereto. For another example, the p-type dopant may include a halogenated metal compound, such as CuI and RbI, a quinone derivative, such as TCNQ (Tetracyanoquinodimethane) and F4-TCNQ (2,3,5,6-tetrafluoro-7,7′8,8′8,8-tetracyanoquinodimethane, etc., and a metal oxide, such as tungsten oxide and molybdenum oxide, but embodiments are not limited thereto.

Each of the first to third light emission layers BEML1, BEML2, and BEML3 and the fourth light emission layer GEML may include a host material and a dopant material. Each of the first to third light emission layers BEML1, BEML2, and BEML3 and the fourth light emission layer GEML may include a material including a carbazole derivative moiety or an amine derivative moiety as a hole-transporting host material. Each of the first to third light emission layers BEML1, BEML2, and BEML3 and the fourth light emission layer GEML may include a material including a nitrogen-containing aromatic ring structure, such as a pyridine derivative moiety, a pyridazine derivative moiety, a pyrimidine derivative moiety, a pyrazine derivative moiety, and a triazine derivative moiety as an electron-transporting host material.

Each of the first to third light emission layers BEML1, BEML2, and BEML3 and the fourth light emission layer GEML may include an anthracene derivative, a pyrene derivative, a fluoranthene derivative, a chrycene derivative, a dihydro benzanthracene derivative, or a triphenylene derivative as a host material. Furthermore, each of the first to third light emission layers BEML1, BEML2, and BEML3 and the fourth light emission layer GEML may further include a general material known in the art as a host material. For example, each of the first to third light emission layers BEML1, BEML2, and BEML3) and the fourth light emission layer GEML may include at least one of DPEPO (Bis[2-(diphenylphosphino)phenyl] ether oxide), CBP (4,4′-Bis(carbazol-9-yl)biphenyl), mCP (1,3-Bis(carbazol-9-yl)benzene), PPF (2,8-Bis(diphenylphosphoryl)dibenzo[b,d]furan), TCTA (4,4′,4″-Tris(carbazol-9-yl)-triphenylamine), and TPBi (1,3,5-tris(1-phenyl-1H-benzo[d]imidazole-2-yl)benzene) as a host material. However, the present disclosure is not limited thereto, and for another example, Alq3 (tris (8-hydroxyquinolino) aluminum), PVK (poly (N-vinylcarbazole), ADN (9,10-di (naphthalene-2-yl) anthracene), TBADN (2-tert-butyl-9,10-di (naphth-2-yl) anthracene), DSA (distyrylarylene), CDBP (4,4′-bis (9-carbazolyl)-2,2′-dimethyl-biphenyl), MADN (2-Methyl-9,10-bis (naphthalen-2-yl) anthracene), CP1 (Hexaphenyl cyclotriphosphazene), UGH2 (1,4-Bis (triphenylsilyl) benzene), DPSiO₃ (Hexaphenylcyclotrisiloxane), DPSiO₄ (Octaphenylcyclotetra siloxane), and the like may be used as the host material.

In one embodiment, the first to third light emission layers BEML1, BEML2, and BEML3) may include a styryl derivative (e.g., 1, 4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and derivatives thereof (e.g., 2, 5, 8, 11-Tetra-t-butylperylene (TBP)), pyrene and its derivatives (e.g., 1, 1-dipyrene, 1, 4-dipyrenylbenzene, 1, 4-Bis(N, N-Diphenylamino)pyrene), and the like, as a known fluorescent dopant material.

The fourth light emission layer GEML may include a known phosphorescent dopant material. For example, the phosphorescent dopant may be a metal complex containing iridium (Ir), platinum (Pt), osmium (Os), gold (Au), titanium (Ti), zirconium (Zr), hafnium (Hf), europium (Eu), terbium (Tb), or thulium (Tm). Specifically, FIrpic (iridium(III) bis(4,6-difluorophenylpyridinato-N, C2′)picolinate, Fir6 (Bis(2,4-difluorophenylpyridinato)-tetrakis(1-pyrazolyl)borate iridium(III)), or platinum octaethyl pyridine (PtOEP) may be used as the phosphorescent dopant.

Each of the electron transport areas ETR1, ETR2, ETR3, and ETR4 may have a single layer formed of a single material, a single layer formed of a plurality of different materials, or a multi-layered structure having a plurality of layers formed of a plurality of different materials. For example, at least some of the electron transport areas ETR1, ETR2, ETR3, and ETR4 may include an electron transport layer ETL4 and an electron injection layer EIL4

Each of the electron transport areas ETR1, ETR2, ETR3, and ETR4 may be formed by using various methods, such as vacuum deposition, spin coating, casting, a Langmuir-Blodgett (LB) method, inkjet printing, laser printing, and laser induced thermal imaging (LITI).

The electron transport areas ETR1, ETR2, ETR3, and ETR4 may include an anthracene-based compound. However, the present disclosure is not limited thereto, and each of the electron transport domains ETR1, ETR2, ETR3, and ETR4 may include, for example, Alq3 (Tris(8-hydroxyquinolinato)aluminum), 1,3,5-tri[(3-pyridyl)-phen-3-yl]benzene, T2T (2,4,6-tris(3′-(pyridin-3-yl)biphenyl-3-yl)-1,3,5-triazine), 2-(4-(N-phenylbenzoimidazol-1-yl)phenyl)-9,10-dinaphthylanthracene, TPBi (1,3,5-Tri(1-phenyl-1H-benzo[d]imidazol-2-yl)benzene), BCP (2,9-Dimethyl-4,7-diphenyl-1,10-phenanthroline), Bphen (4,7-Diphenyl-1,10-phenanthroline), TAZ(3-(4-Biphenylyl)-4-phenyl-5-tert-butylphenyl-1,2,4-triazole), NTAZ(4-(Naphthalen-1-yl)-3,5-diphenyl-4H-1,2,4-triazole), tBu-PBD(2-(4-Biphenylyl)-5-(4-tert-butylphenyl)-1,3,4-oxadiazole), BAlq(Bis(2-methyl-8-quinolinolato-N1,O8)-(1,1′-Biphenyl-4-olato)aluminum), Bebq2(berylliumbis(benzoquinolin-10-olate)), ADN(9,10-di(naphthalene-2-yl)anthracene), BmPyPhB(1,3-Bis[3,5-di(pyridin-3-yl)phenyl]benzene), and mixtures thereof.

Furthermore, each of the electron transport areas ETR1, ETR2, and ETR3 and ETR4 may include a halogenated metal, such as LiF, NaCl, CsF, RbCl, RbI, CuI, and KI, a lanthanum metal, such as Yb, and a co-deposition material of the halogenated metal and a lanthanum metal. For example, the electron transport areas ETR1, ETR2, ETR3, and ETR4 may include KI: Yb, RbI: Yb, or the like as a co-deposition material. The electron transport areas ETR1, ETR2, ETR3, and ETR4 may include at least two materials selected from Mg, Ag, Yb, and Al. For example, the electron transport areas ETR1, ETR2, ETR3, and ETR4 may include Mg and Yb.

Meanwhile, the electron transport areas ETR1, ETR2, ETR3, and ETR4 may be formed of a metal oxide, such as Li2O or BaO, or Liq (8-hydroxyl-Lithium quinolate), but embodiments are not limited thereto. Each of the electron transport areas ETR1, ETR2, ETR3, and ETR4 may also be formed of a material, in which an electron transport material and an insulating organic metal salt are mixed. The organic metal salt may have an energy band gap of about 4 electron volts (eV) or more. For example, the organic metal salt may include metal acetate, metal benzoate, metal acetoacetate, metal acetylacetonate, or metal stearate.

Each of the electron transport areas ETR1, ETR2, ETR3, and ETR4 may further include at least one of BCP (2,9-dimethyl-4,7-diphenyl-1,10-phenanthroline) and Bphen (4,7-diphenyl-1,10-phenanthroline) in addition to the above-described materials, but embodiments are not limited thereto.

The electron transport areas ETR1, ETR2, ETR3, and ETR4 may include the compounds in the electron transport area in the electron injection layer or the electron transport layer. When the electron transport areas ETR1, ETR2, ETR3, and ETR4 include the electron-side additional layer, the electron-side additional layer may include the above-described material. In an embodiment, the electron injection layer EIL4 may include at least two materials selected from Mg, Ag, Yb, and Al. The electron injection layer EIL4 may be formed of, for example, a mixture of Mg and Yb.

A thickness of each of the electron transport areas ETR1, ETR2, ETR3, and ETR4 may be, for example, about 10 nm to about 150 nm. A thickness of the electron transport layer may be about 0.1 nm to about 100 nm, for example, about 0.3 nm to about 50 nm. When the thickness of the electron transport layer satisfies the above-described range, a satisfactory degree of electron transport characteristics may be obtained with no substantial increase in the driving voltage.

The second electrode EL2 is provided on the plurality of light emission stacks ST1, ST2, ST3, and ST4. The second electrode EL2 may be a common electrode. The second electrode EL2 may be a cathode or an anode, but embodiments are not limited thereto. For another example, when the first electrode EL1 is an anode, the second electrode EL2 may be a cathode, and when the first electrode EL1 is a cathode, the second electrode EL2 may be an anode.

The second electrode EL2 may be a transflective electrode or a transmissive electrode. When the second electrode EL2 is a transmissive electrode, the second electrode EL2 may be formed of a transparent metal oxide, for example, indium tin oxide (ITO), indium zinc oxide (IZO), zinc oxide (ZO), indium tin oxide (ITZO), or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture (e.g., AgMg, AgYb, or MgAg) including the above-described element. Alternatively, the second electrode EL2 may be a multi-layered structure including a reflective film formed of the materials, a transflective film, and a transparent conductive film formed of indium tin oxide (ITO), indium zinc oxide (IZO), zinc oxide (ZnO), indium tin zinc oxide (ITZO), and the like. For example, the second electrode EL2 may include the above-described metal materials, a combination of two or more metal materials selected from the above-described metal materials, an oxide of the above-described metal materials, or the like.

Although not illustrated, the second electrode EL2 may be connected to an auxiliary electrode. When the second electrode EL2 is connected to the auxiliary electrode, a resistance of the second electrode EL2 may be reduced.

Meanwhile, a capping layer CPL may be further disposed on the second electrode EL2 of the light emitting element LED according to an embodiment. The capping layer CPL may include multiple layers or a single layer.

In an embodiment, the capping layer CPL may be an organic layer or an inorganic layer. For example, when the capping layer CPL includes an inorganic material, the inorganic material may include an alkali metal compound such as LiF, an alkaline earth metal compound such as MgF2, SiON, SiNX, SiOy, or the like.

For example, when the capping layer CPL includes an organic material, the organic material may include α-NPD, NPB, TPD, m-MTDATA, Alq3, CuPc, TPD15 (N4, N4, N4′, N4′-tetra (biphenyl-4-yl) biphenyl-4,4′-diamine), TCTA (4,4′,4′-tris (carbazol sol-9-yl) triphenylamine), an epoxy resin, or an acrylate such as methacrylate.

As described above, light that travels from the light control pattern to the air layer may be refracted due to a refractive index difference between the light control pattern and the air layer. When the light travels from the light control pattern to the air layer, the refraction angle may be greater than the incident angle. Accordingly, substantially, the light may be diffused in the air layer.

When the light travels from the air layer to the adhesion layer, the color filter layer, or the base layer, the light may be refracted and the refraction angle may be smaller than the incident angle. Accordingly, a straightness of the light may be substantially improved so that the light may be condensed. Thus, the straightness of the light may be substantially improved so that the light may be condensed. Because the light is condensed and emitted through the base layer, the light emission efficiency may be improved.

A transition temperature and a curing temperature of the adhesion layer may be higher than a room temperature. A phenomenon, in which the phase transition or curing of the adhesion layer is performed during the inter-panel coupling process, may be removed or reduced. Accordingly, a reliability of the process of coupling the upper and lower panels may be improved.

Although an embodiment of the present disclosure has been described for illustrative purposes, those skilled in the art will appreciate that various modifications, and substitutions are possible, without departing from the scope and spirit of the present disclosure as disclosed in the accompanying claims. Accordingly, the technical scope of the present disclosure should not be limited to the contents described in the detailed description of the specification but should be defined by the claims.

What is claimed is:

1. A display device comprising:
a light emitting element, which outputs a source light; and
an optical structure layer disposed on the light emitting element, and, which converts the source light into a light of a different wavelength,
wherein the optical structure layer includes:
a light control layer disposed on the light emitting element, and including a first bank, in which a first bank opening is defined, and a first light control pattern disposed in the first bank opening;
a second bank disposed on the light control layer, and in which a second bank opening overlapping the first bank opening in a plan view is defined;
a color filter layer disposed on the second bank; and
an adhesion layer disposed between the second bank and the color filter layer.

2. The display device of claim 1, wherein the second bank includes an organic material or an inorganic material.

3. The display device of claim 1, wherein an air layer is disposed in the second bank opening.

4. The display device of claim 1, wherein a thickness of the second bank is 3 micrometers (μm) to 5μm.

5. The display device of claim 1, wherein in the plan view, an opening overlapping the second bank opening is defined in the adhesion layer.

6. The display device of claim 5, wherein an air layer is disposed in the opening.

7. The display device of claim 1, wherein a thickness of the adhesion layer is 3μm to 5μm.

8. The display device of claim 1, wherein the adhesion layer includes a photocurable resin or a thermophotovoltaic resin.

9. The display device of claim 1, wherein the adhesion layer includes acrylate or epoxide.

10. The display device of claim 1, wherein a curing temperature of the adhesion layer is 80 degrees Celsius (° C.) to 100 degrees Celsius.

11. The display device of claim 1, wherein a transition temperature of the adhesion layer is 50 degrees Celsius to 80 degrees Celsius.

12. The display device of claim 1, wherein the first bank opening is provided in plurality, and
the first light control pattern, a second light control pattern, and a third light control pattern are disposed in the plurality of first bank openings, respectively.

13. The display device of claim 12, wherein the second bank opening is provided in plurality, and in the plan view, the plurality of second bank openings overlap the first bank openings, respectively.

14. The display device of claim 13, wherein an air layer is disposed in the plurality of second bank openings.

15. The display device of claim 13, wherein a plurality of openings overlapping the plurality of second bank openings are defined in the adhesion layer, and an air layer is disposed in the openings.

16. An electronic device comprising:
a camera module;
a display device, which displays an image corresponding to a captured image acquired through the camera module; and
a case accommodating the display device and the camera module,
wherein the display device includes:
a light emitting element, which outputs a source light; and
an optical structure layer disposed on the light emitting element, and, which converts the source light into a light of a different wavelength, and
wherein the optical structure layer includes:
a light control layer disposed on the light emitting element, and including a first bank, in which a first bank opening is defined, and a first light control pattern disposed in the first bank opening;
a second bank disposed on the light control layer, and in which a second bank opening overlapping the first bank opening in a plan view is defined;
a color filter layer disposed on the second bank; and
an adhesion layer disposed between the second bank and the color filter layer.

17. The electronic device of claim 16, wherein an air layer is disposed in the second bank opening.

18. The electronic device of claim 16, wherein in the plan view, an opening overlapping the second bank opening is defined in the adhesion layer, and an air layer is defined in the opening.

19. The electronic device of claim 16, wherein the first bank opening is provided in plurality, and the first light control pattern, a second light control pattern, and a third light control pattern are disposed in the plurality of first bank openings, respectively,
wherein the second bank opening is provided in plurality, and in the plan view, the plurality of second bank openings overlap the first bank openings, respectively, and
wherein an air layer is disposed in the plurality of second bank openings.
